(19) United States
(12) Patent Application Publication
(10) Pub. No.: US 2013/0153116 A1
(43) Pub. Date: Jun. 20, 2013

(54) JOINT SYSTEM, SUBSTRATE PROCESSING SYSTEM, AND JOINT METHOD

(71) Applicants: Osamu Hirakawa, Koshi-shi (JP); Naoto Yoshitaka, Koshi-shi (JP); Masataka Matsunaga, Koshi-shi (JP); Norihiko Okamoto, Koshi-shi (JP)

(72) Inventors: Osamu Hirakawa, Koshi-shi (JP); Naoto Yoshitaka, Koshi-shi (JP); Masataka Matsunaga, Koshi-shi (JP); Norihiko Okamoto, Koshi-shi (JP)

(73) Assignee: TOKYO ELECTRON LIMITED, Tokyo (JP)

(21) Appl. No.: 13/818,356

(22) PCT Filed: Mar. 15, 2011
(86) PCT No.: PCT/JP2011/056698

§ 371 Date: Feb. 22, 2013

(30) Foreign Application Priority Data
Aug. 23, 2010 (JP) 2010-185892
Jan. 7, 2011 (JP) 2011-002549

(51) Int. Cl. H01L 21/673

(52) U.S. Cl. CPC H01L 21/673
USPC 156/64; 156/556; 156/378; 156/536; 156/60

(57) ABSTRACT

The present disclosure includes: a joint processing station including a coating unit applying an adhesive to a processing target substrate or a supporting substrate, a first heat processing unit heating the substrates coated with the adhesive, a second heat processing unit heating the substrates to a higher temperature, a reversing unit reversing front and rear surfaces of the substrate, a joint unit joining the processing target substrate and the supporting substrate together by pressing them, and a transfer region for transferring the substrates to the units; and a transfer-in/out station transferring the substrates into/from the joint processing station.

### CROSS-REFERENCE TO RELATED APPLICATIONS

This application is a 35 U.S.C §371 national stage filling of International Application No. PCT/JPF2011/056698, filed Mar. 15, 2011, the entire contents of which are incorporated by reference herein, which claims priority to Japanese Patent Application Nos. 2010-185892, filed on Aug. 23, 2010; and 2011-002549, filed on Jan. 7, 2011, the entire contents of which are incorporated by reference herein.

### TECHNICAL FIELD

The present disclosure relates to a joint system joining a processing target substrate and a supporting substrate together, a substrate processing system including the joint system, and a joint method using the joint system.

### BACKGROUND

In recent years, for example, in a manufacturing process of a semiconductor device, the diameter of a semiconductor wafer (hereinafter, referred to as a “wafer”) increasingly becomes larger. Further, the wafer is required to be thinner in a specific process such as mounting. For example, when a thin wafer with a large diameter is transferred or subjected to polishing as it is, warpage or break can occur in the wafer. Therefore, in order to reinforce the wafer, for example, bonding the wafer to a wafer being a supporting substrate or a glass substrate is performed.

The bonding of the wafer and the supporting substrate is performed by intervening an adhesive between the wafer and the supporting substrate using, for example, a bond unit. The bond unit has, for example, a first holding member holding the wafer, a second holding member holding the supporting substrate, a heating mechanism heating the adhesive disposed between the wafer and the supporting substrate, and a moving mechanism moving the first holding member and the second holding member in the vertical direction. In the bond unit, the adhesive is supplied between the wafer and the supporting substrate and heated, then the wafer and the supporting substrate are pressed to be bonded together.

However, in the case of using the bond unit described in Patent Document 1, since all of the supply of the adhesive, the heating, and the pressing of the wafer and the supporting substrate are performed in one bond unit, it takes a considerable amount of time to join the wafer and the supporting substrate together. Further, every time the wafer and the supporting substrate are joined together, the temperature of the heating mechanism needs to be increased or decreased for adjustment, and the temperature regulation requires much time. Therefore, there is room to improve the throughput of the whole joint processing.

### SUMMARY

The present disclosure has been made in consideration of the above point, and an object thereof is to efficiently perform joining of a processing target substrate and a supporting substrate and thereby improve the throughput of the joint processing.

To achieve the above object, the present disclosure is a joint system joining a processing target substrate and a supporting substrate together, including: a joint processing station performing predetermined processing on the processing target substrate and the supporting substrate; and a transfer-in/out station transferring the processing target substrate, the supporting substrate or a superposed substrate in which the processing target substrate and the supporting substrate are joined together into/from the joint processing station. Further, the joint processing station includes: a coating unit applying an adhesive to the processing target substrate or the supporting substrate; a first heat processing unit heating the processing target substrate or the supporting substrate coated with the adhesive to a first temperature; a second heat processing unit further heating the processing target substrate or the supporting substrate which has been heated to the first temperature to a second temperature higher than the first temperature; a joint unit joining the processing target substrate and the supporting substrate together via the adhesive by pressing the processing target substrate and the supporting substrate; and a transfer region for transferring the processing target substrate, the supporting substrate or the superposed substrate to the coating unit, the first heat processing unit, the second heat processing unit, and the joint unit.

According to the joint system of the present disclosure, for example, the processing target substrate is processed in sequence in the coating unit, the first heat processing unit, and the second heat processing unit so that the processing target substrate is coated with the adhesive, and the front and rear surfaces of, for example, the supporting substrate are reversed in the reversing unit. Thereafter, the processing target substrate coated with the adhesive is joined with the supporting substrate whose front and rear surfaces have been reversed in the joint unit. As described above, according to the present disclosure, the processing target substrate and the supporting substrate can be concurrently processed. Further, during the time when the processing target substrate and the supporting substrate are being joined together in the joint unit, other processing target substrate and supporting substrate can also be processed in the coating unit, the first heat processing unit, the second heat processing unit and the reversing unit. Further, since the heat processing of the processing target substrate can be performed at two stages in the first heat processing unit and the second heat processing unit, the temperatures of heating mechanisms themselves in the first heat processing unit and the second heat processing unit can be made constant, and temperature regulation of the heating mechanisms does not need to be performed, unlike the prior art. Therefore, it is possible to efficiently perform joining of a processing target substrate and a supporting substrate and thereby improve the throughput of the joint processing. Note that though the adhesive is applied to the processing target substrate and the front and rear surfaces of the supporting substrate are reversed in the above description, the adhesive may be applied to the supporting substrate and the front and rear surfaces of the processing target substrate may be reversed.

When the adhesive applied on the processing target substrate is rapidly heated at a high temperature, the solvent in the adhesive evaporates and can cause projections and depressions on the surface of the adhesive. In this regards, according to the present disclosure, since the heat processing of the processing target substrate can be performed at two stages in the first heat processing unit and the second heat processing unit, the surface of the adhesive can be kept flat. Accordingly, the joint processing of the processing target substrate and the supporting substrate can be appropriately performed.

The present disclosure according to another aspect is a substrate processing system including the joint system, further including a separation system separating the superposed substrate joined by the joint system into the processing target substrate and the supporting substrate, wherein the separation system includes: a separation processing station performing predetermined processing on the processing target substrate, the supporting substrate, and the superposed substrate; a transfer-in/out station transferring the processing target substrate, the supporting substrate or the superposed substrate into/from the separation processing station; and a transfer unit transferring the processing target substrate, the supporting substrate or the superposed substrate between the separation processing station and the transfer-in/out station, and wherein the separation processing station includes: a separation unit separating the superposed substrate into the processing target substrate and the supporting substrate; a first cleaning unit cleaning the processing target substrate separated in the separation unit; and a second cleaning unit cleaning the supporting substrate separated in the separation unit.

The present disclosure according to still another aspect is a joint method of joining a processing target substrate and a supporting substrate together using a joint system, wherein the joint system includes: a joint processing station including a coating unit applying an adhesive to the processing target substrate or the supporting substrate, a first heat processing unit heating the processing target substrate or the supporting substrate coated with the adhesive to a first temperature, a second heat processing unit further heating the processing target substrate or the supporting substrate which has been heated to the first temperature to a second temperature higher than the first temperature, a joint unit joining the processing target substrate and the supporting substrate together via the adhesive by pressing the processing target substrate and the supporting substrate, and a transfer region for transferring the processing target substrate, the supporting substrate or the superposed substrate to the coating unit, the first heat processing unit, the second heat processing unit, and the joint unit; and a transfer-in/out station transferring the processing target substrate, the supporting substrate or the superposed substrate into/from the joint processing station. Further, the joint method includes: an adhesive coating step of applying the adhesive to the processing target substrate or the supporting substrate in the coating unit, then heating the processing target substrate or the supporting substrate to the first temperature in the first heat processing unit, and further heating the processing target substrate or the supporting substrate to the second temperature in the second heat processing unit; and a joint step of then joining, in the joint unit, the processing target substrate or the supporting substrate coated with the adhesive in the adhesive coating step with the supporting substrate or the processing target substrate.

According to the present disclosure, it is possible to efficiently perform joining of the processing target substrate and the supporting substrate and thereby improve the throughput of the joint processing.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating the outline of a configuration of a joint system according to this embodiment.

FIG. 2 is a side view illustrating the outline of an internal configuration of the joint system according to this embodiment.

FIG. 3 is a side view of a processing target wafer and a supporting wafer.

FIG. 4 is a longitudinal sectional view illustrating the outline of a configuration of a joint unit.

FIG. 5 is a longitudinal sectional view illustrating the outline of the configuration of the joint unit.

FIG. 6 is a longitudinal sectional view illustrating the outline of a configuration of a coating unit.

FIG. 7 is a transverse sectional view illustrating the outline of the configuration of the coating unit.

FIG. 8 is a longitudinal sectional view illustrating the outline of a configuration of a first heat processing unit.

FIG. 9 is a transverse sectional view illustrating the outline of the configuration of the first heat processing unit.

FIG. 10 is an explanatory view of airflows occurring in the joint system.

FIG. 11 is a flowchart illustrating main steps of joint processing.

FIG. 12 is an explanatory view illustrating the appearance in which a first holing part is raised.

FIG. 13 is an explanatory view illustrating the appearance in which the central portion of a second holding part bends.

FIG. 14 is an explanatory view illustrating the appearance in which the entire joint surface of a supporting wafer is in contact with the entire joint surface of a processing target wafer.

FIG. 15 is an explanatory view illustrating the appearance in which the processing target wafer and the supporting wafer are joined together.

FIG. 16 is a side view illustrating the outline of an internal configuration of a joint system according to another embodiment.

FIG. 17 is a longitudinal sectional view illustrating the outline of a configuration of an inspection unit.

FIG. 18 is a transverse sectional view illustrating the outline of the configuration of the inspection unit.

FIG. 19 is a plan view illustrating the outline of a configuration of a substrate processing system including the joint system and the separation system.

FIG. 20 is a side view of a processing target wafer and a supporting wafer.

FIG. 21 is a longitudinal sectional view illustrating the outline of a configuration of a separation unit.

FIG. 22 is a longitudinal sectional view illustrating the outline of a configuration of a first cleaning unit.

FIG. 23 is a transverse sectional view illustrating the outline of a configuration of the first cleaning unit.

FIG. 24 is a longitudinal sectional view illustrating the outline of a configuration of a second cleaning unit.

FIG. 25 is a longitudinal sectional view illustrating the outline of a configuration of a second transfer unit.

FIG. 26 is a flowchart illustrating main steps of separation processing.

FIG. 27 is an explanatory view illustrating the appearance in which a superposed wafer is held by the first holding part and the second holding part.

FIG. 28 is an explanatory view illustrating the appearance in which the second holding part is moved in the vertical direction and the horizontal direction.

FIG. 29 is an explanatory view illustrating the appearance in which the processing target wafer and the supporting wafer are separated.

FIG. 30 is an explanatory view illustrating the appearance in which the processing target wafer is delivered from the first holding part to a Bernoulli chuck.

FIG. 31 is an explanatory view illustrating the appearance in which the processing target wafer is delivered from the Bernoulli chuck to a porous chuck.

FIG. 32 is a plan view illustrating the outline of a configuration of a separation system according to another embodiment.

FIG. 33 is a plan view illustrating the outline of a configuration of a separation system according to another embodiment.

FIG. 34 is a plan view illustrating the outline of a configuration of a joint system according to another embodiment.

FIG. 35 is a transverse sectional view illustrating the outline of a configuration of a joint unit.

FIG. 36 is a plan view illustrating the outline of a configuration of a delivery part.

FIG. 37 is a plan view illustrating the outline of a configuration of a delivery arm.

FIG. 38 is a side view illustrating the outline of the configuration of the delivery arm.

FIG. 39 is a plan view illustrating the outline of a configuration of a reversing part.

FIG. 40 is a side view illustrating the outline of the configuration of the reversing part.

FIG. 41 is a side view illustrating the outline of the configuration of the reversing part.

FIG. 42 is a side view illustrating the outline of a configuration of a holding arm and a holding member.

FIG. 43 is a side view illustrating the outline of a configuration of a transfer part.

FIG. 44 is an explanatory view illustrating the appearance in which the transfer part is arranged in the joint unit.

FIG. 45 is a plan view illustrating the outline of a configuration of a first transfer arm.

FIG. 46 is a side view illustrating the outline of the configuration of the first transfer arm.

FIG. 47 is a plan view illustrating the outline of a configuration of a second transfer arm.

FIG. 48 is a side view illustrating the outline of the configuration of the second transfer arm.

FIG. 49 is an explanatory view illustrating the appearance in which cutouts are formed in the second holding part.

FIG. 50 is a flowchart illustrating main steps of joint processing according to another embodiment.

### DETAILED DESCRIPTION

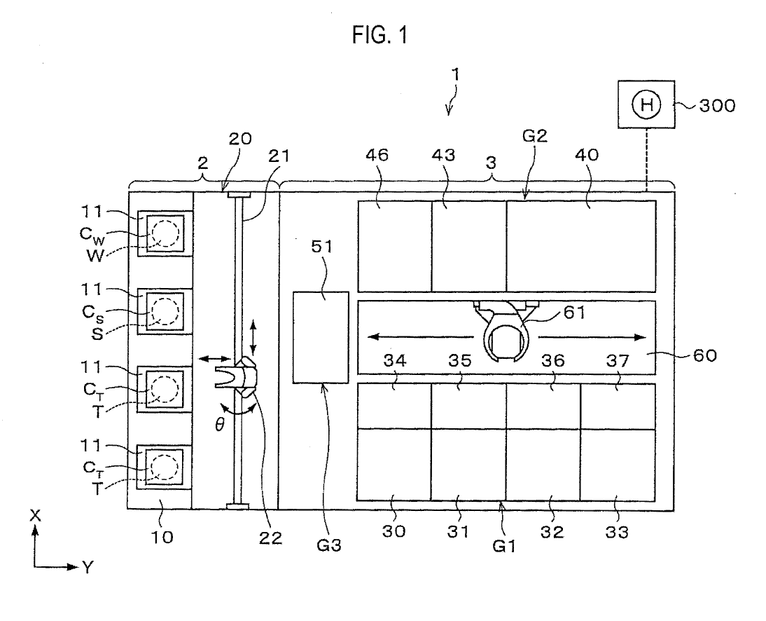

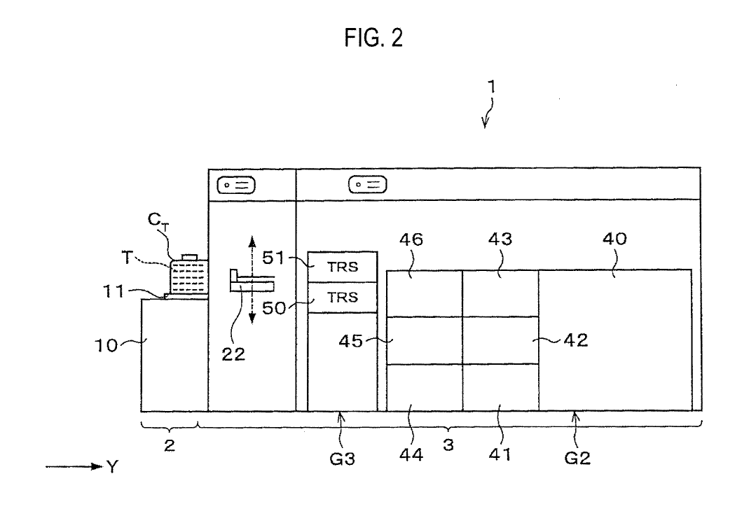

Hereinafter, embodiments of the present disclosure will be described. FIG. 1 is a plan view illustrating the outline of a configuration of a joint system 1 according to this embodiment. FIG. 2 is a side view illustrating the outline of an internal configuration of the joint system 1.

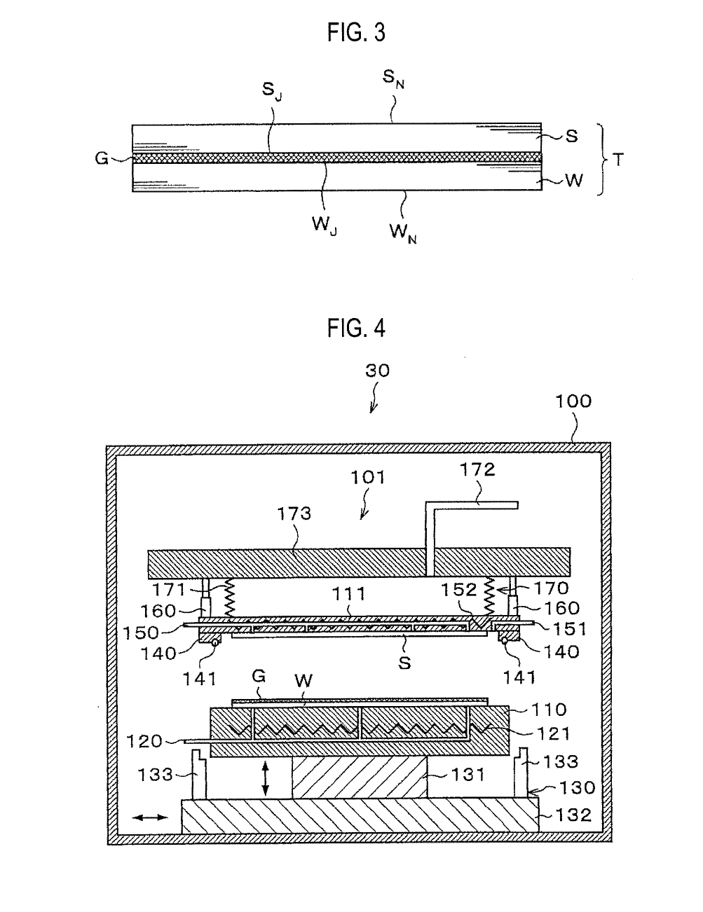

In the joint system 1, a processing target wafer W as a processing target substrate and a supporting wafer S as a supporting substrate are joined together via an adhesive G as illustrated in FIG. 3. Hereinafter, in the processing target wafer W, the surface to be joined with the supporting wafer S via the adhesive G is referred to as a “joint surface W_{J}” as a front surface and the surface opposite the joint surface W_{J} is referred to as “a non-joint surface W_{N}” as a rear surface. Similarly, in the supporting wafer S, the surface to be joined with the processing target wafer W via the adhesive G is referred to as a “joint surface S_{J}” as a front surface and the surface opposite the joint surface S_{J} is referred to as “a non-joint surface S_{N}” as a rear surface. In the joint system 1, the processing target wafer W and the supporting wafer S are joined together to form a superposed wafer T as a superposed substrate. Note that the processing target wafer W is a wafer which will be a product, and a plurality of electronic circuits have been formed, for example, on the joint surface W_{J} and the non-joint surface W_{N} will be subjected to polishing processing. Further, the supporting wafer S is a wafer which has the same diameter as that of the processing target wafer W and supports the processing target wafer W. Note that the case of using a wafer as the supporting substrate will be described in this embodiment, but other substrates such as, for example, a glass substrate and the like may be used.

The joint system 1 has, as illustrates in FIG. 1, a configuration in which a transfer-in/out station 2 into/from which cassettes C_{W}, C_{S}, C_{T} capable of housing a plurality of processing target wafers W, a plurality of supporting wafers S, and a plurality of superposed wafers T respectively are transferred from/to the outside, and a joint processing station 3 including various processing and treatment units performing predetermined processing and treatment on the processing target wafer W, the supporting wafer S, and the superposed wafer T are integrally connected.

In the transfer-in/out station 2, a cassette mounting table 10 is provided. On the cassette mounting table 10, a plurality of, for example, four cassette mounting plates 11 are provided. The cassette mounting plates 11 are arranged side by side in a line in an X-direction (a top-bottom direction in FIG. 1). On these cassette mounting plates 11, the cassettes C_{W}, C_{S}, C_{T} can be mounted when the cassettes C_{W}, C_{S}, C_{T} are transferred in/out from/to the outside of the joint system 1. As described above, the transfer-in/out station 2 is configured to be capable of holding the plurality of processing target wafers W, the plurality of supporting wafers S, and the plurality of superposed wafers T. Note that the number of cassette mounting plates 11 is not limited to this embodiment but can be arbitrarily determined. Further, one of the cassettes may be used for collecting defect wafers. In other words, this cassette is a cassette capable of separating wafers having defect generated in joint between the processing target wafer W and the supporting wafer S due to various causes, from normal superposed wafers T. In this embodiment, one cassette C_{T} of the plurality of cassettes C_{T} is used for collecting the defect wafers, and the other cassettes C_{T} are used for collecting normal superposed wafers T.

In the transfer-in/out station 2, a wafer transfer part 20 is provided adjacent to the cassette mounting table 10. In the wafer transfer part 20, a wafer transfer unit 22 movable on a transfer path 21 extending in the X-direction is provided. The wafer transfer unit 22 is also movable in the vertical direction and around the vertical axis (in a θ-direction), and thus can transfer the processing target wafer W, the supporting wafer S, the superposed wafer T between the cassettes C_{W}, C_{S}, C_{T} on the cassette mounting plates 11 and later-described transition units 50, 51 in a third processing block G3 of the joint processing station 3.

In the joint processing station 3, a plurality of, for example, three processing blocks G1, G2, G3 each including various processing and treatment units are arranged. The first processing block G1 is provided on the front side (an X-direction negative direction side in FIG. 1) of the joint processing station 3, and the second processing block G2 is provided on the rear side (an X-direction positive direction side in FIG. 1) in the joint processing station 3. Further, the third processing block G3 is provided on the transfer-in/out station 2 side (a Y-direction negative direction side in FIG. 1) in the joint processing station 3.

For example, on the front side (the X-direction negative direction side in FIG. 1) in the first processing block G1, joint units 30 to 33 each joining the processing target wafer W and the supporting wafer S together via the adhesive G by pressing them are arranged side by side in the Y-direction in this order from the transfer-in/out station 2 side. Further, on the rear side (the X-direction positive direction side in FIG. 1) in the first processing block G1, for example, reversing units 34 to 37 each reversing the front and rear surfaces of, for example, the supporting wafer S are arranged side by side in the Y-direction in this order from the transfer-in/out station 2 side. The joint units 30 to 33 and the reversing units 34 to 37 are arranged in a one-to-one correspondence.

For example, in the second processing block G2, as illustrated in FIG. 2, a coating unit 40 applying an adhesive G to the processing target wafer W, first heat processing units 41 to 43 each heating the processing target wafer W coated with the adhesive G to a first temperature, and second heat processing units 44 to 46 each further heating the processing target wafer W, which has been heated to the first temperature, to a second temperature higher than the first temperature are arranged side by side in this order in a direction toward the transfer-in/out station 2 side (the Y-direction negative direction in FIG. 1). The first heat processing units 41 to 43 are three-tiered in this order from the bottom. Similarly, the second heat processing units 44 to 46 are three-tiered in this order from the bottom.

For example, in the third processing block G3, the transition units 50, 51 for the processing target wafer W, the supporting wafer S, the superposed wafer T are two-tiered in this order from the bottom.

As illustrated in FIG. 1, in a region surrounded by the first processing block G1 to the third processing block G3, a wafer transfer region 60 is formed. In the wafer transfer region 60, for example, a wafer transfer unit 61 is disposed. Note that the pressure in the wafer transfer region 60 is equal to or higher than the atmospheric pressure, and so-called transfer in the atmospheric system of the processing target wafer W, the supporting wafer S, the superposed wafer T is performed in the wafer transfer region 60.

The wafer transfer unit 61 has a transfer arm movable, for example, in the vertical direction, the horizontal directions (the X-direction, the Y-direction), and around the vertical axis. The wafer transfer unit 61 can move in the wafer transfer region 60 and transfer the processing target wafer W, the supporting wafer S, and the superposed wafer T to predetermined units in the first processing block G1, the second processing block G2 and the third processing block G3 therearound.

Next, the configurations of the above-described joint units 30 to 33 will be described. The joint unit 30 has a processing container 100 hermetically closable the inside thereof as illustrated in FIG. 4. In the side surface on the wafer transfer region 60 side of the processing container 100, a transfer-in/out port (not illustrated) for the processing target wafer W, the supporting wafer S, and the superposed wafer T is formed, and an opening/closing shutter (not illustrated) is provided at the transfer-in/out port.

Inside the processing container 100, a joint part 101 joining the processing target wafer W and the supporting wafer S together via the adhesive G by pressing them is provided. The joint part 101 has a first holding part 110 mounting and holding the processing target wafer W by its upper surface, and a second holding part 111 suction-holding the supporting wafer S by its lower surface. The first holding part 110 is provided below the second holding part 111 and disposed to face the second holding part 111. In other words, the processing target wafer W held by the first holding part 110 and the supporting wafer S held by the second holding part 111 are arranged to face each other.

Inside the first holding part 110, a suction pipe 120 for suction-holding the processing target wafer W is provided. The suction pipe 120 is connected to a negative pressure generating device (not illustrated) such as, for example, a vacuum pump. Note that for the first holding part 110, a material having strength preventing deformation even if a load is applied thereon by a later-described pressurizing mechanism 170, for example, ceramics such as silicon carbide ceramic, aluminum nitride ceramic or the like is used.

Further, inside the first holding part 110, a heating mechanism 121 heating the processing target wafer W is provided. For the heating mechanism 121, for example, a heater is used.

Below the first holding part 110, a moving mechanism 130 moving the first holding part 110 and the processing target wafer W in the vertical direction and the horizontal direction is provided. The moving mechanism 130 can three-dimensionally move the first holding part 110 with an accuracy of, for example, ±1 μm. The moving mechanism 130 has a vertical moving part 131 moving the first holding part 110 in the vertical direction and a horizontal moving part 132 moving the first holding part 110 in the horizontal direction. Each of the vertical moving part 131 and the horizontal moving part 132 has, for example, a ball screw (not illustrated) and a motor (not illustrated) turning the ball screw. Note that below the first holding part 110, raising and lowering pins (not illustrated) for delivering the processing target wafer W are provided. The raising and lowering pins pass through the first holding part 110 in the thickness direction thereof and are configured to freely rise and lower in the vertical direction.

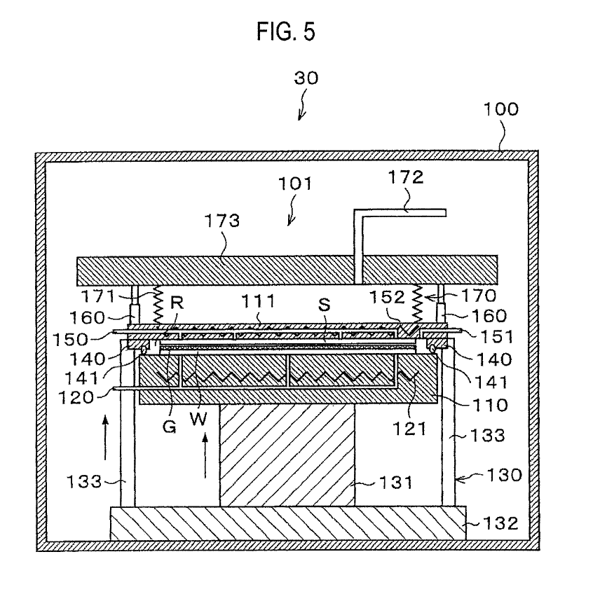

On the horizontal moving part 132, supporting members 133 extensible and contractible in the vertical direction are provided. The supporting members 133 are provided, for example, at three locations outside the first holding part 110. The supporting members 133 can support a projection part 140 provided projecting from the outer peripheral lower surface of the second holding part 111 as illustrated in FIG. 5.

By the above moving mechanism 130, the processing target wafer W on the first holding part 110 can be aligned in the horizontal direction, and the first holding part 110 can be raised to form a joint space R for joining the processing target wafer W and the supporting wafer S together as illustrated in FIG. 5. The joint space R is a space surrounded by the first holding part 110, the second holding part 111 and the projection part 140. Further by adjusting the heights of the supporting members 133 when forming the joint space R, the distance between the processing target wafer W and the supporting wafer S in the joint space R can be adjusted.

Note that below the first holding part 110, raising and lowering pins (not illustrated) for supporting the processing target wafer W or the superposed wafer T from below and raising and lowering it are provided. The raising and lowering pins pass through through holes (not illustrated) formed in the first holding part 110 and can project from the upper surface of the first holding part 110.

For the second holding part 111, for example, aluminum that is an elastic body is used. Then, the second holding part 111 is configured such that when a predetermined pressure, for example, 0.7 atmosphere (=0.07 MPa) is applied on the entire surface of the second holding part 111, a portion thereof, for example, a central portion bends as will be described later.

On the outer peripheral lower surface of the second holding part 111, the above-described projection part 140 projecting downward from the outer peripheral lower surface is formed as illustrated in FIG. 4. The projection part 140 is formed along the outer periphery of the second holding part 111. Note that the projection part 140 may be formed integrally with the second holding part 111.

On the lower surface of the projection part 140, a sealing material 141 for keeping the air tightness of the joint space R is provided. The sealing material 141 is annularly provided in a groove formed in the lower surface of the projection part 140 and, for example, an O-ring is used therefor. Further, the sealing material 141 has elasticity. Note that the sealing material 141 only needs to be a component having a sealing function and is not limited to this embodiment.

Inside the second holding part 111, a suction pipe 150 for suction-holding the supporting wafer S is provided. The suction pipe 150 is connected to a negative pressure generating device (not illustrated) such as, for example, a vacuum pump.

Further, inside the second holding part 111, a suction pipe 151 for sucking the atmosphere in the joint space R is provided. One end of the suction pipe 151 is opened in the lower surface of the second holding part 111 at a location where the supporting wafer S is not held. Further, the other end of the suction pipe 151 is connected to a negative pressure generating device (not illustrated) such as, for example, a vacuum pump.

Further, inside the second holding part 111, a heating mechanism 152 heating the supporting wafer S is provided. For the heating mechanism 152, for example, a heater is used.

On the upper surface of the second holding part 111, supporting members 160 supporting the second holding part 111 and a pressurizing mechanism 170 pressing the second holding part 111 vertically downward are provided. The pressurizing mechanism 170 has a pressure container 171 provided in a manner to cover the processing target wafer W and the supporting wafer S, and a fluid supply pipe 172 supplying fluid, for example, compressed air into the pressure container 171. Further, the supporting members 160 are configured to be extensible and contractible in the vertical direction and provided, for example, at three locations outside the pressure container 171.

The pressure container 171 is composed of bellows made of, for example, stainless steel, which is extensible and contractible, for example, in the vertical direction. The pressure container 171 has a lower surface in abutment with the upper surface of the second holding part 111 and an upper surface in abutment with the lower surface of a supporting plate 173 provided above the second holding part 111. The fluid supply pipe 172 has one end connected to the pressure container 171 and the other end connected to a fluid supply source (not illustrated). Then, a fluid is supplied from the fluid supply pipe 172 into the pressure container 171, whereby the pressure container 171 extends. In this event, since the upper surface of the pressure container 171 is in abutment with the lower surface of the supporting plate 173, the pressure container 171 extends only downward to be able to press the second holding part 111 provided on the lower surface of the pressure container 171 downward. Further, in this event, the inside of the pressure container 171 is pressurized by the fluid, so that the pressure container 171 can uniformly press the second holding part 111. Adjustment of the load when pressing the second holding part 111 is performed by adjusting the pressure of the compressed air to be supplied to the pressure container 171. Note that the supporting plate 173 is preferably composed of a member having strength preventing deformation even if it receives the reaction force of the load applied on the second holding part 111 by the pressurizing mechanism 170. Note that the supporting plate 173 of this embodiment may be omitted, and the upper surface of the pressure container 171 may be in abutment with the ceiling surface of the processing container 100.

Note that the configurations of the joint units 31 to 33 are the same as that of the above-described joint unit 30, and therefore the description thereof is omitted.

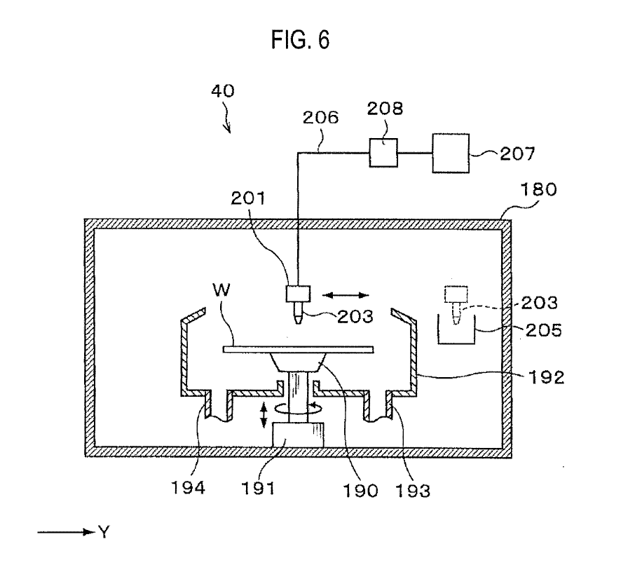

Next, the configuration of the above-described coating unit 40 will be described. The coating unit 40 has a treatment container 180 hermetically closable the inside thereof as illustrated in FIG. 6. In the side surface on the wafer transfer region 60 side of the treatment container 180, a transfer-in/out port (not illustrated) for the processing target wafer W is formed, and an opening/closing shutter (not illustrated) is provided at the transfer-in/out port.

At a central portion in the treatment container 180, a spin chuck 190 holding and rotating the processing target wafer W is provided. The spin chuck 190 has a horizontal upper surface, and a suction port (not illustrated) sucking, for example, the processing target wafer W is provided in the upper surface. By suction through the suction port, the processing target wafer W can be suction-held on the spin chuck 190.

Below the spin chuck 190, a chuck driving part 191 equipped with, for example, a motor and so on is provided. The spin chuck 190 can rotate at a predetermined speed by means of the chuck driving part 191. Further, the chuck driving part 191 is provided with a raising and lowering driving source such as, for example, a cylinder and can freely rise and lower.

Around the spin chuck 190, a cup 192 is provided which receives and collects liquid splashing or dropping from the processing target wafer W. A drain pipe 193 draining the collected liquid and an exhaust pipe 194 evacuating and exhausting the atmosphere in the cup 192 are connected to the lower surface of the cup 192.

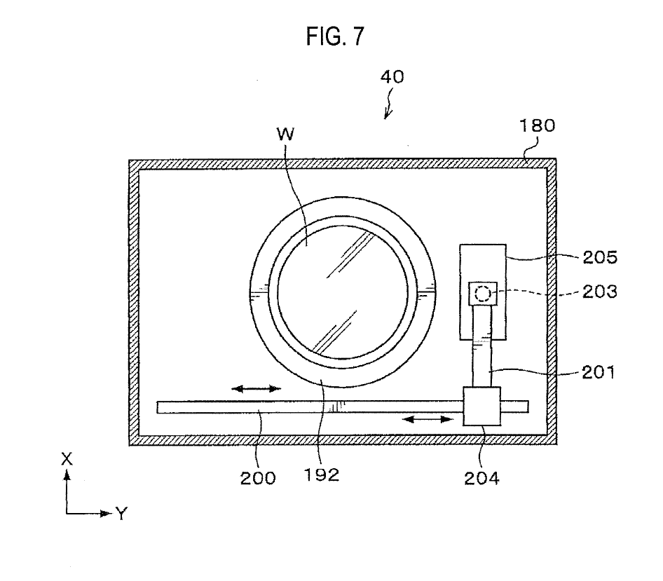

As illustrated in FIG. 7, on an X-direction negative direction (a downward direction in FIG. 7) side of the cup 192, a rail 200 extending along a Y-direction (a right-left direction in FIG. 7) is formed. The rail 200 is formed, for example, from a Y-direction negative direction (a left direction in FIG. 7) side outer position of the cup 192 to a Y-direction positive direction (a right direction in FIG. 7) side outer position. On the rail 200, for example, an arm 201 is attached.

On the arm 201, an adhesive nozzle 203 supplying a liquid adhesive G onto the processing target wafer W is supported as illustrated in FIG. 6 and FIG. 7. The arm 201 is movable on the rail 200 by means of a nozzle driving part 204 illustrated in FIG. 7. Thus, the adhesive nozzle 203 can move from a waiting section 205 provided at the Y-direction positive direction side outer position of the cup 192 to a position above a central portion of the processing target wafer W in the cup 192, and further move in the diameter direction of the processing target wafer W above the processing target wafer W. Further, the arm 201 can freely rise and lower by means of the nozzle driving part 204 to be able to adjust the height of the adhesive nozzle 203.

To the adhesive nozzle 203, a supply pipe 206 supplying the adhesive G to the adhesive nozzle 203 is connected as illustrated in FIG. 6. The supply pipe 206 communicates with an adhesive supply source storing the adhesive G therein. Along the supply pipe 206, a supply equipment group 208 is provided which includes a valve, a flow regulator and so on for controlling the flow of the adhesive G.

Incidentally, a back rinse nozzle (not illustrated) jetting a cleaning solution toward the rear surface of the processing target substrate W, namely, the non-joint surface W_{N} may be provided below the spin chuck 190. The cleaning solution jetted from the back rinse nozzle cleans the non-joint surface W_{N} of the processing target wafer W and the outer peripheral portion of the processing target substrate W.

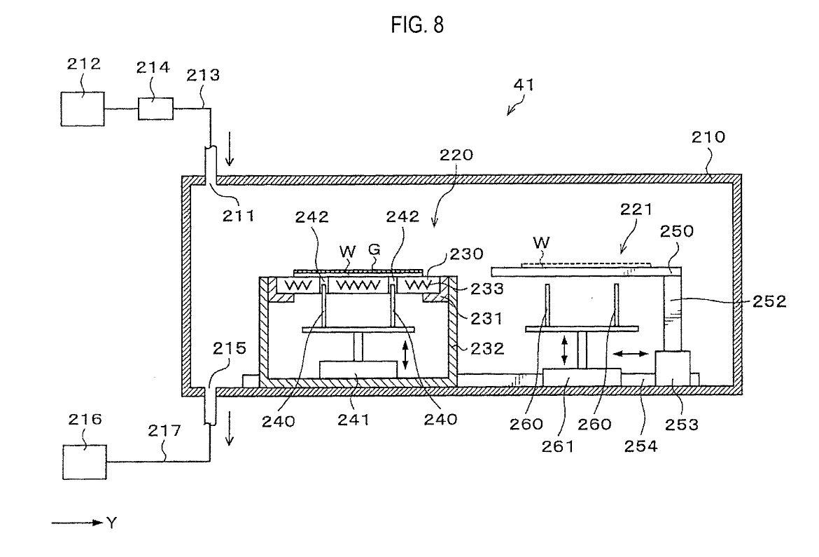

Next, the configurations of the above-described first heat processing units 41 to 43 will be described. The heat processing unit 41 has a processing container 210 hermetically closable the inside thereof as illustrated in FIG. 8. In the side surface on the wafer transfer region 60 side of the processing container 210, a transfer-in/out port (not illustrated) for the processing target wafer W is formed, and an opening/closing shutter (not illustrated) is provided at the transfer-in/out port.

At the ceiling surface of the processing container 210, a gas supply port 211 supplying an inert gas, for example, a nitrogen gas into the processing container 210 is formed. To the gas supply port 211, a gas supply pipe 213 communicating with a gas supply source 212 is connected. Along the gas supply pipe 213, a supply equipment group 214 is provided which includes a valve, a flow regulator and so on for controlling the flow of the inert gas.

At the bottom surface of the processing container 210, a suction port 215 sucking the atmosphere in the processing container 210 is formed. A suction pipe 217 communicating with a negative pressure generating device 216 such as, for example, a vacuum pump is connected to the suction port 215.

Inside the processing container 210, a heating part 220 performing heat processing on the processing target wafer W and a temperature regulation part 221 temperature-regulating the processing target wafer W are provided. The heating part 220 and the temperature regulation part 221 are arranged side by side in the Y-direction.

The heating part 220 includes an annular holding member 231 accommodating a heating plate 230 and holding the outer peripheral portion of the heating plate 230, and a cylindrical support ring 232 surrounding the outer periphery of the holding member 231. The heating plate 230 has an almost disk shape with a large thickness and can mount and heat the processing target wafer W thereon. Further, for example, a heater 233 is embedded in the heating plate 230. The heating temperature of the heating plate 230 is controlled, for example, by a control unit 300 so that the processing target wafer W mounted on the heating plate 230 is heated to a predetermined temperature.

Below the heating plate 230, for example, three raising and lowering pins 240 for supporting the processing target wafer W from below and raising and lowering it are provided. The raising and lowering pins 240 can vertically move by means of a raising and lowering driving part 241. Near the middle portion of the heating plate 230, through holes 242 penetrating the heating plate 230 in the thickness direction are formed, for example, at three locations. Then, the raising and lowering pins 240 pass through the through holes 242 and can project from the upper surface of the heating plate 230.

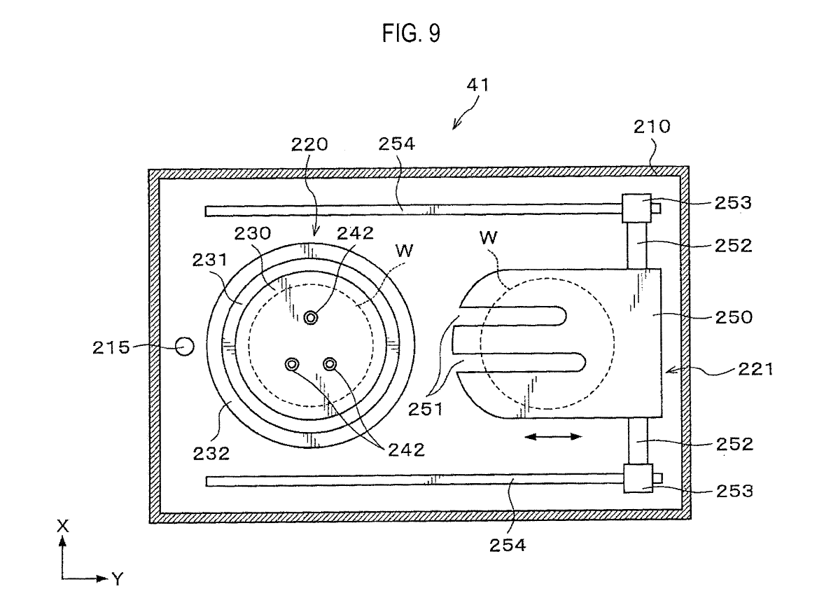

The temperature regulation part 221 has a temperature regulation plate 250. The temperature regulation plate 250 has an almost square flat plate shape as illustrated in FIG. 9 and has an end face on the heating plate 230 side curved in an arc shape. In the temperature regulation plate 250, two slits 251 are formed along the Y-direction. The slits 251 are formed from the end face on the heating plate 230 side of the temperature regulation plate 250 to the vicinity of the middle portion of the temperature regulation plate 250. The slits 251 can prevent the temperature regulation plate 250 from interfering with the raising and lowering pins 240 of the heating part 220 and later-described raising and lowering pins 260 of the temperature regulation part 221. Further, in the temperature regulation plate 250, a temperature regulation member (not illustrated) such as a Peltier element is embedded. The cooling temperature of the temperature regulation plate 250 is controlled, for example, by the control unit 300 so that the processing target wafer W mounted on the temperature regulation plate 250 is cooled to a predetermined temperature.

The temperature regulation plate 250 is supported on a supporting arm 252 as illustrated in FIG. 8. On the supporting arm 252, a driving part 253 is attached. The driving part 253 is attached on a rail 254 extending in the Y-direction. The rail 254 extends from the temperature regulation part 221 to the heating part 220. By means of the driving part 253, the temperature regulation plate 250 can move along the rail 254 between the heating part 220 and the temperature regulation part 221.

Below the temperature regulation plate 250, for example, three raising and lowering pins 260 for supporting the processing target wafer W from below and raising and lowering it are provided. The raising and lowering pins 260 can vertically move by means of a raising and lowering driving part 261. Then, the raising and lowering pins 260 pass through the slits 251 and can project from the upper surface of the temperature regulation plate 250.

Note that the configurations of the first heat processing units 42, 43 are the same as that of the above-described first heat processing unit 41, and therefore the description thereof is omitted. Further, the configurations of the second heat processing units 44 to 46 are also the same as that of the above-described first heat processing unit 41, and therefore the description thereof is omitted.

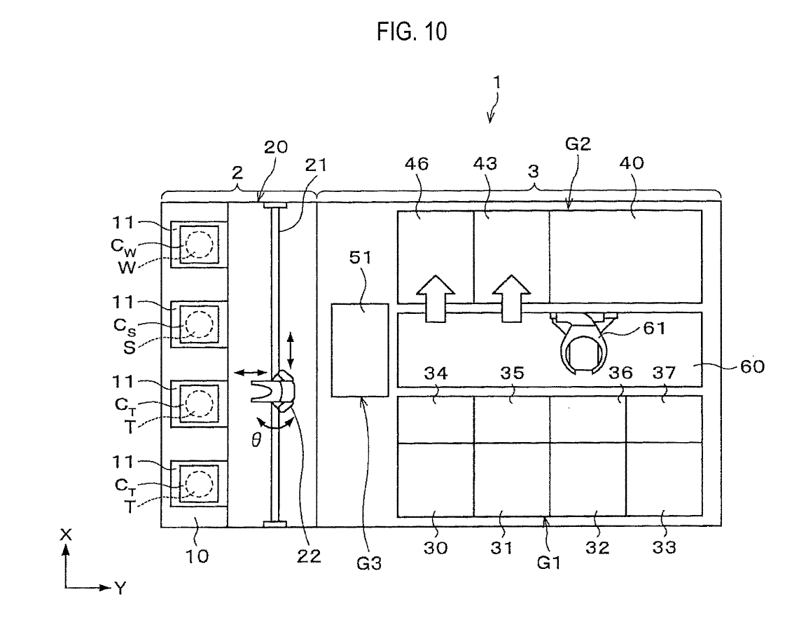

Further, when the joint processing of the processing target wafer W and the supporting wafer S is performed in the joint system 1, the pressures in the above-described first heat processing units 41 to 43 and the pressures in the above-described second heat processing units 44 to 46 are negative pressures with respect to the wafer transfer region 60. Therefore, when the opening/closing shutter of the processing container 210 of each of the heat processing units 41 to 46 is opened, airflows directing from the wafer transfer region 60 to each of the heat processing units 41 to 46 occur as indicated by arrows in FIG. 10.

In the above joint system 1, the control unit 300 is provided as illustrated in FIG. 1. The control unit 300 is, for example, a computer and has a program storage part (not illustrated). In the program storage part, a program is stored which controls the processing of the processing target wafer W, the supporting wafer S, and the superposed wafer T in the joint system 1. Further, the program storage part also stores a program controlling the operation of the driving system such as the above-described various processing and treatment units and transfer units to implement the later-described joint processing in the joint system 1. Note that the program may be the one that is stored, for example, in a computer-readable storage medium H such as a computer-readable hard disk (HD), flexible disk (FD), compact disk (CD), magneto-optical disk (MO), or memory card, and installed from the storage medium H into the control unit 300.

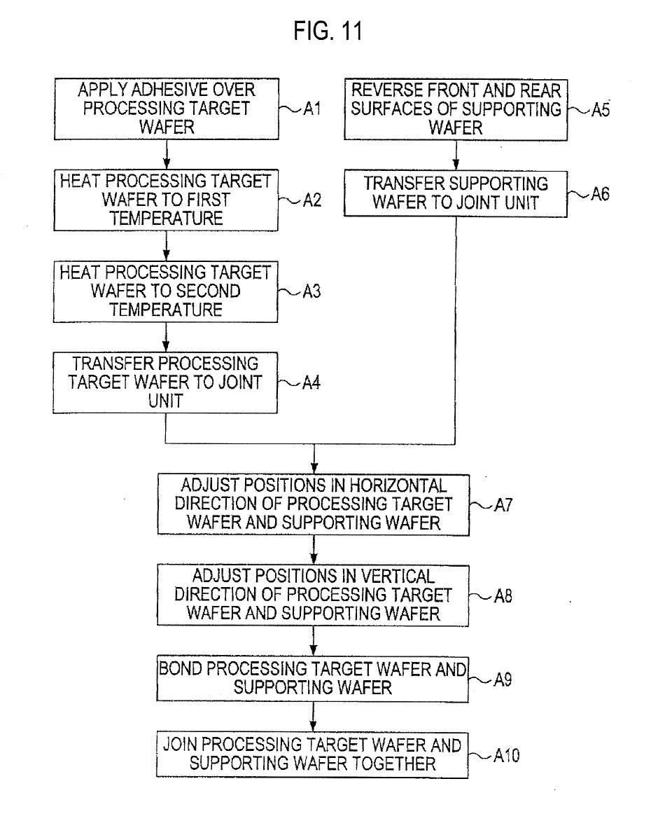

Next, the joint processing method of the processing target wafer W and the supporting wafer S performed using the joint system 1 configured as described above will be described. FIG. 11 is a flowchart illustrating an example, of main steps of the joint processing.

First, a cassette C_{W} housing a plurality of processing target wafers W, a cassette C_{S} housing a plurality of supporting wafers S, and an empty cassette C_{T} are mounted on the predetermined cassette mounting plates 11 in the transfer-in/out station 2. Then, a processing target wafer W in the cassette C_{W} is taken out by the wafer transfer unit 22 and transferred to the transition unit 50 in the third processing block G3 of the joint processing station 3. In this event, the processing target wafer W is transferred with the non-joint surface W_{N} facing downward.

Subsequently, the processing target wafer W is transferred by the wafer transfer unit 61 to the coating unit 40. The processing target wafer W transferred in the coating unit 40 is delivered from the wafer transfer unit 61 to the spin chuck 190 and suction-held thereon. In this event, the non joint surface W_{N} of the processing target wafer W is suction-held.

Subsequently, the arm 201 moves the adhesive nozzle 203 at the waiting section 205 to a position above a central portion of the processing target wafer W. Thereafter, while the processing target wafer W is being rotated by the spin chuck 190, the adhesive G is supplied from the adhesive nozzle 203 to the joint surface W_{J} of the processing target wafer W. The supplied adhesive G is diffused over the entire joint surface W_{J} of the processing target wafer W by the centrifugal force, whereby the adhesive G is applied over the joint surface W_{J} of the processing target wafer W (Step A1 in FIG. 11).

Subsequently, the processing target wafer W is transferred by the wafer transfer unit 61 to the first heat processing unit 41. Once the processing target wafer W is transferred into the first heat processing unit 41, the processing target wafer W is delivered from the wafer transfer unit 61 to the raising and lowering pins 260 which have been raised and waiting in advance. Subsequently, the raising and lowering pins 260 are lowered to mount the processing target wafer W on the temperature regulation plate 250.

Thereafter, the temperature regulation plate 250 is moved by the driving part 253 to above the heating plate 230 along the rail 254, and the processing target wafer W is delivered to the raising and lowering pins 240 which have been raised and waiting and waiting in advance. Thereafter, the raising and lowering pins 240 are lowered to mount the processing target wafer W on the heating plate 230. Then, the processing target wafer W on the heating plate 230 is heated to a first temperature, for example, 100° C. to 150° C. (Step A2 in FIG. 11). The heating performed by the heating plate 230 heats the adhesive G on the processing target wafer W so that the adhesive G hardens.

Thereafter, the raising and lowering pins 240 are raised and the temperature regulation plate 250 is moved to above the heating plate 230. Subsequently, the processing target wafer W is delivered from the raising and lowering pins 240 to the temperature regulation plate 250, and the temperature regulation plate 250 is moved to the wafer transfer region 60 side. During the movement of the temperature regulation plate 250, the processing target wafer W is temperature-regulated to a predetermined temperature.

Then, the processing target wafer W is transferred by the wafer transfer unit 61 to the second heat processing unit 44. Then, in the second heat processing unit 44, the processing target wafer W is heated to a second temperature, for example, 150° C. to 250° C. (Step A3 in FIG. 11). By performing the heating, the adhesive G on the processing target wafer W is heated so that the adhesive G becomes completely hardened. Note that the heat processing of the processing target wafer W in the second heat processing unit 44 is the same as the heat processing of the processing target wafer W in the first heat processing unit 41, and therefore the description thereof is omitted.

The processing target wafer W which has been subjected to heat processing in the second heat processing unit 44 is transferred by the wafer transfer unit 61 passing the reversing unit 34 to the joint unit 30 (Step A4 in FIG. 11). The processing target wafer W transferred to the joint unit 30 is mounted on the first holding part 110. On the first holding part 110, the processing target wafer W is mounted with the joint surface W_{J} thereof facing upward, namely, the adhesive G facing upward.

During the time when the above-described processing at Steps A1 to A4 is performed on the processing target wafer W, processing of the supporting wafer S is performed subsequent to the processing target wafer W. First, a supporting wafer S in the cassette C_{S} is taken out by the wafer transfer unit 22 and transferred to the transition unit 50 in the joint processing station 3. In this event, the supporting wafer S is transferred with the non-joint surface S_{N} facing downward.

Then, the supporting wafer S is transferred by the wafer transfer unit 61 to the reversing unit 34. In the reversing unit 34, the front and rear surfaces of the supporting wafer S are reversed (Step A5 in FIG. 11). In short, the joint surface S_{J} of the supporting wafer S is directed downward.

Thereafter, the supporting wafer S is transferred to the joint unit 30 (Step A6 in FIG. 11). The supporting wafer S transferred in the joint unit 30 is suction-held by the second holding part 111 with the joint surface S_{J} facing downward.

In the joint unit 30, once the processing target wafer W and the supporting wafer S are held by the first holding part 110 and the second holding part 111 respectively, the position in the horizontal direction of the first holding part 110 is adjusted by the moving mechanism 130 so that the processing target wafer W opposes the supporting wafer S (Step A7 in FIG. 11). Note that in this event, the pressure between the second holding part 111 and the supporting wafer S is, for example, 0.1 atmosphere (=0.01 MPa). Further, the pressure applied on the upper surface of the second holding part 111 is 1.0 atmosphere (=0.1 MPa) that is the atmospheric pressure. To maintain the atmospheric pressure applied on the upper surface of the second holding part 111, the pressure in the pressure container 171 of the pressurizing mechanism 170 may be the atmospheric pressure, or a gap may be formed between the upper surface of the second holding part 111 and the pressure container 171.

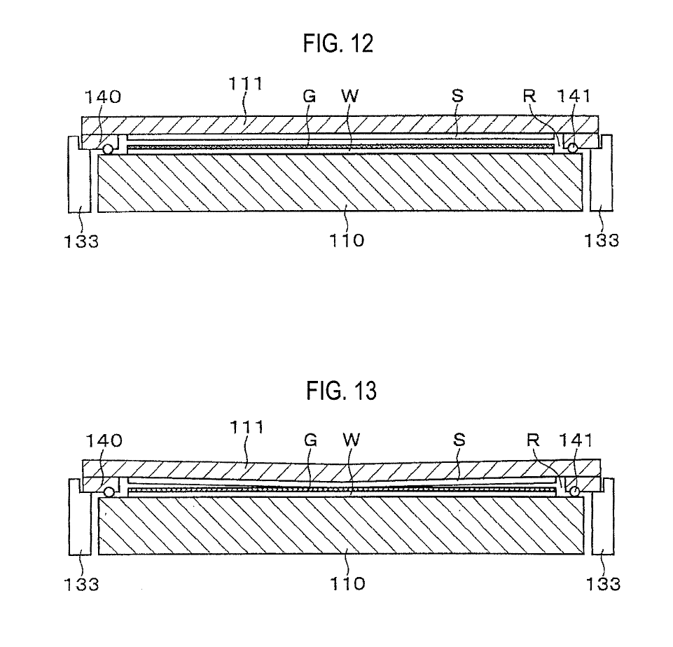

Then, as illustrated in FIG. 12, the moving mechanism 130 raises the first holding part 110 and the supporting members 133 are extended, whereby the second holding part 111 is supported by the supporting members 133. In this event, by adjusting the heights of the supporting members 133, the distance in the vertical direction between the processing target wafer W and the supporting wafer S is adjusted to be a predetermined distance (Step A8 in FIG. 11). Note that this predetermined distance is the height ensuring that the central portion of the supporting wafer S comes into contact with the processing target wafer W when the sealing material 141 comes into contact with the first holding part 110 and the central portions of the second holding part 111 and the supporting wafer S bend as will be described later. In this manner, the joint space R is formed between the first holding part 110 and the second holding part 111.

Thereafter, the atmosphere in the joint space R is sucked from the suction pipe 151. Then, once the pressure in the joint space R is reduced, for example, to 0.3 atmosphere (=0.03 MPa), the pressure difference between the pressure applied on the upper surface of the second holding part 111 and the pressure in the joint space R, namely, 0.7 atmosphere (=0.07 MPa) is applied on the second holding part 111. Then, the central portion of the second holding part 111 bends as illustrated in FIG. 13, and the central portion of the supporting wafer S held by the second holding part 111 also bends. Note that since the pressure between the second holding part 111 and the supporting wafer S is 0.1 atmosphere (=0.01 MPa) even when the pressure in the joint space R is reduced down to 0.3 atmosphere (=0.03 MPa), the supporting wafer S is kept held by the second holding part 111.

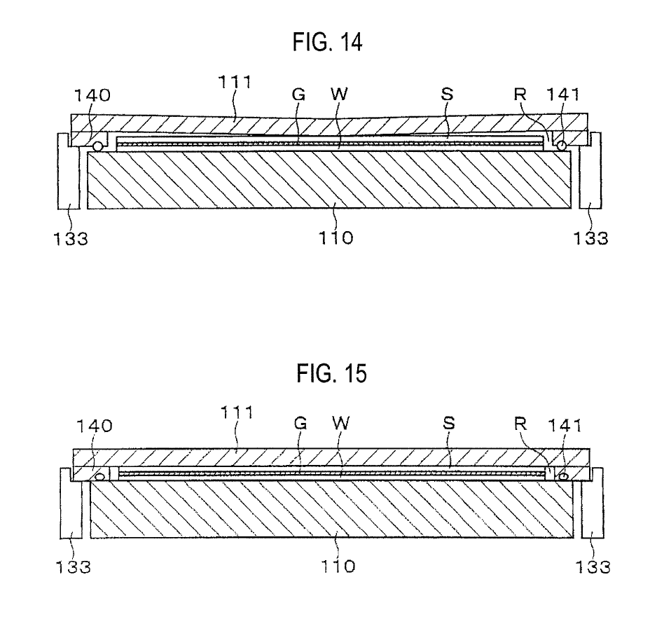

Thereafter, the atmosphere in the joint space R is sucked to reduce the pressure in the joint space R. Then, once the pressure in the joint space R becomes 0.1 atmosphere (=0.01 MPa) or lower, the second holding part 111 cannot hold the supporting wafer S any longer, so that the supporting wafer S falls down as illustrated in FIG. 14 and the entire joint surface S_{J} of the supporting wafer S comes into abutment with the entire joint surface W_{J} of the processing target wafer W. In this event, the supporting wafer S comes into abutment with the processing target wafer W in sequence from the abutted central portion toward the outside in the diameter direction. In other words, even when air that can be a void exists in the joint space R, the air exists at all times outside the position where the supporting wafer S is in abutment with the processing target wafer W, so that the air can escape from between the processing target wafer W and the supporting wafer S. In this manner, the processing target wafer W and the supporting wafer S are bonded together with the adhesive G while suppressing the occurrence of a void (Step A9 in FIG. 11).

Thereafter, as illustrated in FIG. 15, the heights of the supporting members 133 are adjusted to bring the lower surface of the second holding part 111 into contact with the non-joint surface S_{N} of the supporting wafer S. In this event, the sealing material 141 elastically deforms to bring the first holding part 110 and the second holding part 111 into close contact. Then, while the heating mechanisms 121, 152 are heating the processing target wafer W and the supporting wafer S to a predetermined temperature, for example, 200° C., the pressurizing mechanism 170 presses the second holding part 111 downward at a predetermined pressure, for example, 0.5 MPa. Then, the processing target wafer W and the supporting wafer S are more tightly bonded and joined together (Step A10 in FIG. 11).

The superposed wafer T in which the processing target wafer W and the supporting wafer S are joined together is transferred by the wafer transfer unit 61 to the transition unit 51, and then transferred by the wafer transfer unit 22 in the transfer-in/out station 2 to the cassette C_{T} on the predetermined cassette mounting plate 11. In this manner, a series of joint processing of the processing target wafer W and the supporting wafer S ends.

According to the above embodiment, the processing target wafer W is processed in sequence in the coating unit 40, the first heat processing unit 41, and the second heat processing unit 44 and thereby coated with the adhesive G, and the front and rear surfaces of the supporting wafer S are reversed in the reversing unit 34. Thereafter, in the joint unit 30, the processing target wafer W coated with the adhesive G and the supporting wafer S whose front and rear surfaces are reversed are joined together. According to this embodiment, the processing target wafer W and the supporting wafer S can be concurrently processed as described above. Further, during the time when the processing target wafer W and the supporting wafer S are joined together in the joint unit 30, other processing target wafer W and supporting wafer S can also be processed in the coating unit 40, the first heat processing unit 41, the second heat processing unit 44 and the reversing unit 34. Accordingly, the joining of the processing target wafer W and the supporting wafer S can be efficiently performed, and the throughput of the joint processing can be improved.

Further, since the heat processing of the processing target wafer W can be performed at two stages in the first heat processing unit 41 and the second heat processing unit 44, the temperatures of the heating mechanisms themselves in the first heat processing unit 41 and the second heat processing unit 44 can be made constant. Accordingly, temperature regulation of the heating mechanisms does not need to be performed, unlike the prior art, and the throughput of the joint processing can further be improved.

Further, when the adhesive G applied on the processing target wafer W is rapidly heated at a high temperature, the solvent in the adhesive G evaporates so that projections and depressions sometimes occur on the surface of the adhesive G. In this regard, according to this embodiment, the heat processing of the processing target wafer W can be performed at two stages in the first heat processing unit 41 and the second heat processing unit 44, so that the surface of the adhesive G can be kept flat. Accordingly, the joint processing of the processing target wafer W and the supporting wafer S can be appropriately performed.

Further, since an inert gas atmosphere can be kept in each of the first heat processing unit 41 and in the second heat processing unit 44, it is possible to prevent formation of an oxide film on the processing target wafer W. Therefore, the heat processing of the processing target wafer W can be appropriately performed.

Further, the pressures in the first heat processing unit 41 and the pressure in the second heat processing unit 44 are negative pressures with respect to the pressure in the wafer transfer region 60. Therefore, when the opening/closing shutter of the processing container of each of the heat processing units 41, 44 is opened, airflows directing from the wafer transfer region 60 to each of the heat processing units 41, 44 are generated. Accordingly, the heated atmosphere in each of the heat processing units 41, 44 does not flow into the wafer transfer region 60, and the processing target wafer W, the supporting wafer S, the superposed wafer T which is transferred in the wafer transfer region 60 can be appropriately transferred at a predetermined temperature.

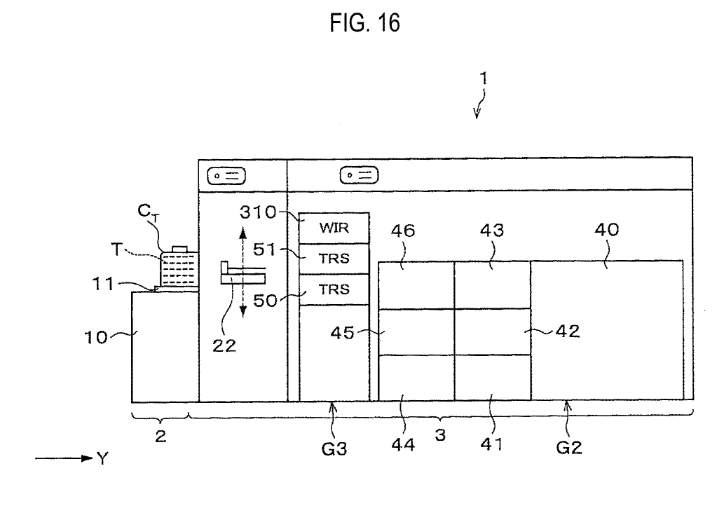

In the joint system 1 in the above embodiment, an inspection unit 310 inspecting the superposed wafer T made by joining in the joint unit 30 may further be provided as illustrated in FIG. 16. The inspection unit 310 is arranged, for example, at the uppermost layer of the third processing block G3.

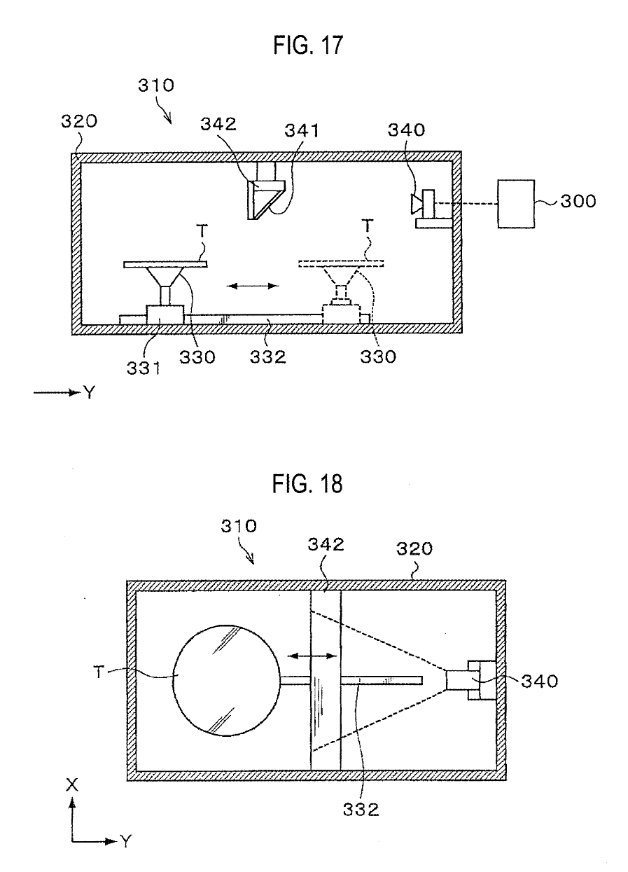

The inspection unit 310 has a processing container 320 as illustrated in FIG. 17. In the side surface on the wafer transfer region 60 side of the processing container 320, a transfer-in/out port (not illustrated) for transferring in/out the superposed wafer T is formed, and an opening/closing shutter (not illustrated) is provided at the transfer-in/out port.

Inside the processing container 320, a chuck 330 suction-holding the superposed wafer T is provided as illustrated in FIG. 17. This chuck 330 freely rotates and stops by means of a chuck driving part 331 equipped with, for example, a motor and so on, and has an alignment function of adjusting the position of the superposed wafer T. On the bottom surface of the processing container 320, a rail 332 extending from one end side (a Y-direction negative direction side in FIG. 17) in the processing container 320 to the other end side (a Y-direction positive direction side in FIG. 17) is provided. The chuck driving part 331 is attached on the rail 332. By means of the chuck driving part 331, the chuck 330 is movable along the rail 332 and can freely rise and lower.

On the side surface on the other end side (a Y-direction positive direction side in FIG. 17) in the processing container 320, an image capturing part 340 is provided. For the image capturing part 340, for example, a wide-angle CCD camera is used. Near an upper middle portion of the processing container 320, a half mirror 341 is provided. The half mirror 341 is provided at a position opposing the image capturing part 340 in a manner to be inclined at 45 degrees from the vertical direction. Above the half mirror 341, an infrared-ray irradiation part 342 irradiating the superposed wafer T with infrared rays is provided, and the half mirror 341 and the infrared-ray irradiation part 342 are fixed on the upper surface of the processing container 320. Further, the infrared-ray irradiation part 342 extends in the X-direction as illustrated in FIG. 18.

In this case, the superposed wafer T joined at Step A10 in the above-described joint unit 30 is transferred by the wafer transfer unit 61 to the inspection unit 310. The superposed wafer T transferred in the inspection unit 310 is delivered from the wafer transfer unit 61 to the chuck 330. Thereafter, the chuck 330 is moved by the chuck driving part 331 along the rail 332, and the moving superposed wafer T is irradiated with the infrared rays from the infrared-ray irradiation part 342. Then, an image of the entire surface of the superposed wafer T is captured by the mage capturing part 340 via the half mirror 341. The captured image of the superposed wafer T is outputted to the control unit 300, and whether or not the joining of the superposed wafer T is appropriately performed in the control unit 300, for example, the presence or absence of void in the superposed wafer T is inspected. Thereafter, the superposed wafer T is transferred by the wafer transfer unit 61 to the transition unit 51 and then transferred by the wafer transfer unit 22 in the transfer-in/out station 2 to the cassette C_{T} on the predetermined cassette mounting plate 11.

According to the above embodiment, since the superposed wafer T can be inspected in the inspection unit 310, the processing condition in the joint system 1 can be corrected based on the inspection result. Accordingly, the processing target wafer W and the supporting wafer S can be further appropriately joined together.

Further, in the joint system 1 of the above embodiment, a temperature regulator (not illustrated) cooling the processing target wafer W, which has been heated in the second heat processing unit 44, to a predetermined temperature may be provided. In this case, since the temperature of the processing target wafer W is regulated to an appropriate temperature, the processing subsequent thereto can be more smoothly performed.

Note that though the processing target wafer W and the supporting wafer S are joined together with the processing target wafer W arranged on the lower side and the supporting wafer S arranged on the upper side in the above embodiment, the vertical arrangement of the processing target wafer W and the supporting wafer S may be reversed. In this case, the above-described Steps A1 to A4 are performed on the supporting wafer S and the adhesive G is applied on the joint surface S_{J} of the supporting wafer S. Further, the above-described Steps A5 and A6 are performed on the processing target wafer W and the front and rear surfaces of the processing target wafer W are reversed. Then, the above-described Steps A7 to A10 are performed to join the supporting wafer S and the processing target wafer W together.

Further, though the adhesive G is applied on one of the processing target wafer W and the supporting wafer S in the coating unit 40 in the above embodiment, the adhesive G may be applied on both of the processing target wafer W and the supporting wafer S.

Further, though the first holding part 110 is moved in the vertical direction and the horizontal direction in the joint unit 30 in the above embodiment, the second holding part 111 may be moved in the vertical direction and the horizontal direction. Alternatively, both the first holding part 110 and the second holding part 111 may be moved in the vertical direction and the horizontal direction.

Further, the coating unit 40 has one adhesive nozzle 203 in the above embodiment but may have, for example, two adhesive nozzles. This case can also cope with the case of using two kinds of adhesives. Further, one adhesive can be used for evaluating the joining.

Here, the superposed wafer T joined in the joint system 1 is subjected to a predetermined processing such as polishing processing and the like on the non-joint surface W_{N} of the processing target wafer W outside the joint system 1. Thereafter, the superposed wafer T is separated into the processing target wafer W and the supporting wafer S, whereby the processing target wafer W is made into a product.

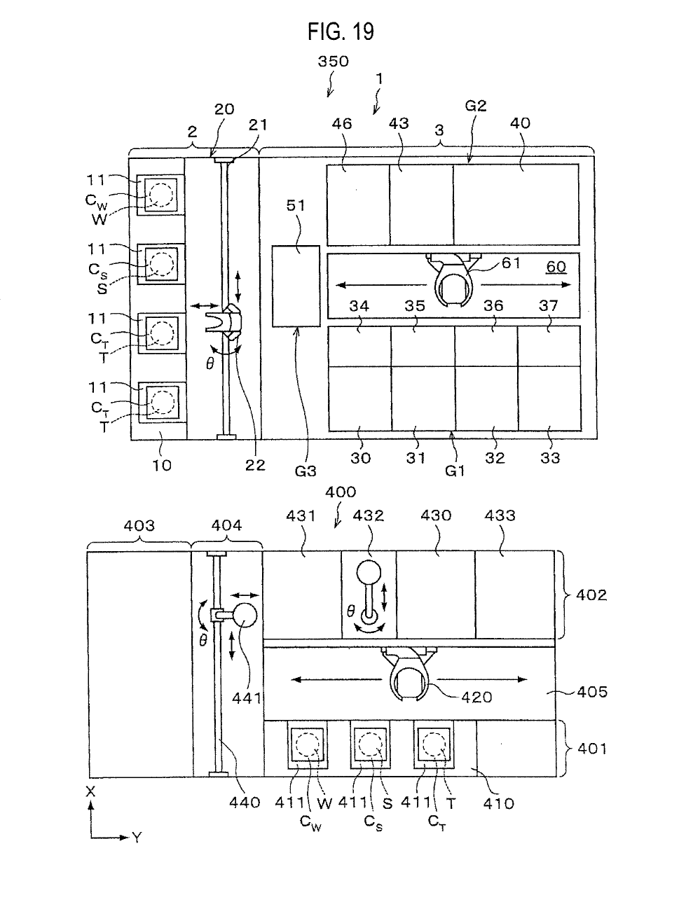

In this embodiment, a substrate processing system 350 including the joint system 1 may further have a separation system 400 separating the superposed wafer T into the processing target wafer W and the supporting wafer S as illustrated in FIG. 19.

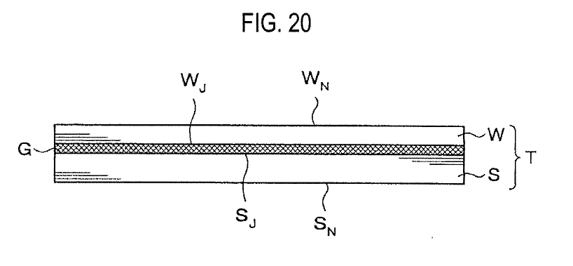

In the separation system 400, the superposed wafer T made by joining with the adhesive G illustrated in FIG. 20 is separated into the processing target wafer W and the supporting wafer S. In this event, on the joint surface W_{J} of the processing target wafer W, a plurality of electronic circuits have been formed as described above. Further, the non joint surface W_{N} of the processing target wafer W has been subjected to polishing processing and the like so that the processing target wafer W has been thinned (for example, a thickness of 50 μm).

The separation system 400 has, as illustrates in FIG. 19, a configuration in which a transfer-in/out station 401 into/from which cassettes C_{W}, C_{S}, C_{T} capable of housing a plurality of processing target wafers W, a plurality of supporting wafers S, and a plurality of superposed wafers T respectively are transferred from/to the outside, a separation processing station 402 including various processing and treatment units performing predetermined processing and treatment on the processing target wafer W, the supporting wafer S, and the superposed wafer T, and an interface station 404 delivering the processing target wafer W to/from a post-processing station 403 adjacent to the separation processing station 402, are integrally connected.

The transfer-in/out station 401 and the separation processing station 402 are arranged side by side in an X-direction (a top-bottom direction in FIG. 19). Between the transfer-in/out station 401 and the separation processing station 402, a wafer transfer region 405 is formed. Further, the interface station 404 is located on a Y-direction negative direction side (a left direction side in FIG. 19) of the transfer-in/out station 401, the separation processing station 402 and the wafer transfer region 405.

In the transfer-in/out station 401, a cassette mounting table 410 is provided. On the cassette mounting table 410, a plurality of, for example, three cassette mounting plates 411 are provided. The cassette mounting plates 411 are arranged side by side in a line in a Y-direction (a right-left direction in FIG. 19). On these cassette mounting plates 411, the cassettes C_{W}, C_{S}, C_{T} can be mounted when the cassettes C_{W}, C_{S}, C_{T} are transferred in/out from/to the outside of the separation system 400. As described above, the transfer-in/out station 401 is configured to be capable of holding the plurality of processing target wafers W, the plurality of supporting wafers S, and the plurality of superposed wafers T. Note that the number of cassette mounting plates 411 is not limited to this embodiment but can be arbitrarily determined. Further, the plurality of superposed wafers T transferred into the transfer-in/out station 401 have been subjected to inspection in advance and discriminated between a superposed wafer T including a normal processing target wafer W and a superposed wafer T including a defective processing target wafer W.

In the wafer transfer region 405, a first transfer unit 420 is disposed. The first transfer unit 420 has, for example, a transfer arm which is movable, for example, in the vertical direction, the horizontal directions (the X-direction, the Y-direction), and around the vertical axis. The first transfer unit 420 can move in the wafer transfer region 405 and transfer the processing target wafer W, the supporting wafer S, the superposed wafer T between the transfer-in/out station 401 and the separation processing station 402.

The separation processing station 402 has a separation unit 430 separating the superposed wafer T into the processing target wafer W and the supporting wafer S. On the Y-direction negative direction side (a left direction side in FIG. 19) of the separation unit 430, a first cleaning unit 431 cleaning the separated processing target wafer W is disposed. Between the separation unit 430 and the first cleaning unit 431, a second transfer unit 432 as another transfer unit is provided. Further, the Y-direction positive direction side (a right direction side in FIG. 19) of the separation unit 430, a second cleaning unit 433 cleaning the separated supporting wafer S is disposed. As described above, in the separation processing station 402, the first cleaning unit 431, the second transfer unit 432, the separation unit 430, and the second cleaning unit 433 are arranged side by side in this order from the interface station 404 side.

In the interface station 404, a third transfer unit 441 as another transfer unit which is movable on a transfer path 440 extending in the X-direction is provided. The third transfer unit 441 is also movable in the vertical direction and around the vertical axis (in a O-direction), and thus can transfer the processing target wafer W between the separation processing station 402 and the post-processing station 403.

Note that in the post-processing station 403, predetermined post-processing is performed on the processing target wafer W separated in the separation processing station 402. As the predetermined post-processing, for example, processing of mounting the processing target wafer W, processing of performing inspection of electric characteristics of the electronic circuits on the processing target wafer W, processing of dicing the processing target wafer W into chips are performed.

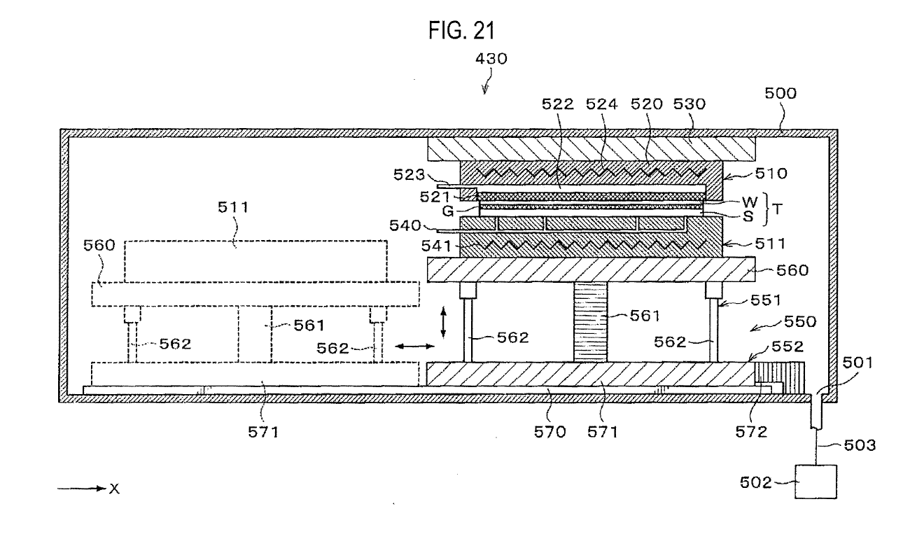

Next, the configuration of the above-described separation unit 430 will be described. The separation unit 430 has a processing container 500 hermetically closable the inside thereof as illustrated in FIG. 21. In the side surface of the processing container 500, a transfer-in/out port (not illustrated) for the processing target wafer W, the supporting wafer S, and the superposed wafer T is formed, and an opening/closing shutter (not illustrated) is provided at the transfer-in/out port.

At the bottom surface of the processing container 500, a suction port 501 sucking the atmosphere in the processing container 500 is formed. A suction pipe 503 communicating with a negative pressure generating device 502 such as, for example, a vacuum pump is connected to the suction port 501.

Inside the processing container 500, a first holding part 510 suction-holding the processing target wafer W by its lower surface, and a second holding part 511 mounting and holding the supporting wafer S on its upper surface are provided. The first holding part 510 is provided above the second holding part 511 and disposed to face the second holding part 511. In other words, inside the processing container 500, the separation processing is performed on the superposed wafer T with the processing target wafer W arranged on the upper side and the supporting wafer S arranged on the lower side.

For the first holding part 510, for example, a porous chuck is used. The first holding part 510 has a main body part 520 in a flat plate shape. On the lower surface side of the main body part 520, a porous body 521 is provided. The porous body 521 has, for example, substantially the same diameter as that of the processing target wafer W and is in abutment with the non-joint surface W_{N} of the processing target wafer W. Note that as the porous body 521, for example, silicon carbide is used.

Further, a suction space 522 is formed inside the main body part 520 and above the porous body 521. The suction space 522 is formed, for example, in a manner to cover the porous body 521. To the suction space 522, a suction pipe 523 is connected. The suction pipe 523 is connected to a negative pressure generating device (not illustrated) such as, for example, a vacuum pump. Then, the non-joint surface W_{N} of the processing target wafer is sucked from the suction pipe 523 via the suction space 522 and the porous body 521 so that the processing target wafer W is suction-held by the first holding part 510.

Further, inside the main body part 520 and above the suction space 522, a heating mechanism 524 heating the processing target wafer W is provided. For the heating mechanism 524, for example, a heater is used.

On the upper surface of the first holding part 510, a supporting plate 530 supporting the first holding part is provided. The supporting plate 530 is supported on the ceiling surface of the processing container 500. Note that the supporting plate 530 of this embodiment may be omitted, and the first holding part 510 may be supported in abutment with the ceiling surface of the processing container 500.

Inside the second holding part 511, a suction pipe 540 for suction-holding the supporting wafer S is provided. The suction pipe 540 is connected to a negative pressure generating device (not illustrated) such as, for example, a vacuum pump.

Further, inside the second holding part 511, a heating mechanism 541 heating the supporting wafer S is provided. For the heating mechanism 541, for example, a heater is used.

Below the second holding part 511, a moving mechanism 550 moving the second holding part 511 and the supporting wafer S in the vertical direction and the horizontal direction is provided. The moving mechanism 550 has a vertical moving part 551 moving the second holding part 511 in the vertical direction and a horizontal moving part 552 moving the second holding part 511 in the horizontal direction.

The vertical moving part 551 has a supporting plate 560 supporting the lower surface of the second holding part 511, a driving part 561 raising and lowering the supporting plate 560, and supporting members 562 supporting the supporting plate 560. The driving part 561 has, for example, a ball screw (not illustrated) and a motor (not illustrated) turning the ball screw. Further, the supporting members 562 are configured to be extensible and contractible in the vertical direction, and provided, for example at three locations between the supporting plate 560 and a later-described supporting body 571.

The horizontal moving part 552 has a rail 570 extending along an X-direction (a right-left direction in FIG. 21), the supporting body 571 attached to the rail 570, and a driving part 572 moving the supporting body 571 along the rail 570. The driving part 572 has, for example, a ball screw (not illustrated) and a motor (not illustrated) turning the ball screw.

Note that below the second holding part 511, raising and lowering pins (not illustrated) for supporting the superposed wafer T or the supporting wafer S from below and raising and lowering it are provided. The raising and lowering pins pass through through holes (not illustrated) formed in the second holding part 511 and can project from the upper surface of the second holding part 511.

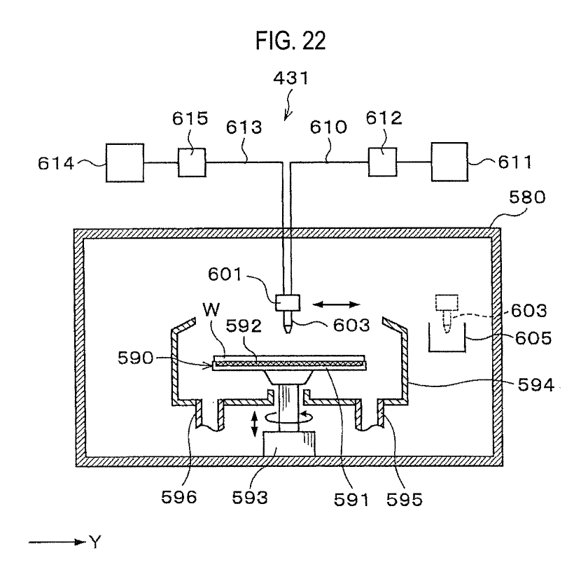

Next, the configuration of the above-described first cleaning unit 431 will be described. The first cleaning unit 431 has a processing container 580 hermetically closable the inside thereof as illustrated in FIG. 22. In the side surface of the processing container 580, a transfer-in/out port (not illustrated) for the processing target wafer W is formed, and an opening/closing shutter (not illustrated) is provided at the transfer-in/out port.

At a center portion inside the processing container 580, a porous chuck 590 mounting and rotating the processing target wafer W thereon is provided. The porous chuck 590 has a main body part 591 in a flat plate shape and a porous body 592 provided on the upper surface side of the main body part 591. The porous body 592 has, for example, substantially the same diameter as that of the processing target wafer W and is in abutment with the non-joint surface W_{N} of the processing target wafer W. Note that as the porous body 592, for example, silicon carbide is used. A suction pipe (not illustrated) is connected to the porous body 592 and sucks the non-joint surface W_{N} of the processing target wafer W via the porous body 592 from the suction pipe and thereby can suction-hold the processing target wafer W on the porous chuck 590.

Below the porous chuck 590, a chuck driving part 593 equipped with, for example, a motor is provided. The porous chuck 590 can rotate at a predetermined speed by means of the chuck driving part 593. Further, the chuck driving part 593 is provided with a raising and lowering driving source such as, for example, a cylinder so that the porous chuck 590 can freely rise and lower.

Around the porous chuck 590, a cup 594 is provided which receives and collects liquid splashing or dropping from the processing target wafer W. A drain pipe 595 draining the collected liquid and an exhaust pipe 596 evacuating and exhausting the atmosphere in the cup 594 are connected to the lower surface of the cup 594.

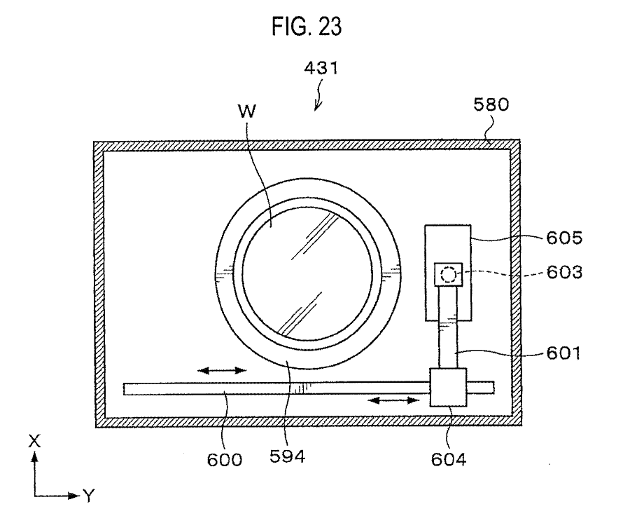

As illustrated in FIG. 23, on an X-direction negative direction (a downward direction in FIG. 23) side of the cup 594, a rail 600 extending along a Y-direction (a right-left direction in FIG. 23) is formed. The rail 600 is formed, for example, from a Y-direction negative direction (a left direction in FIG. 23) side outer position of the cup 594 to a Y-direction positive direction (a right direction in FIG. 23) side outer position. On the rail 600, an arm 601 is attached.

On the arm 601, a cleaning solution nozzle 603 supplying a cleaning solution, for example, an organic solvent onto the processing target wafer W is supported as illustrated in FIG. 22 and FIG. 23. The arm 601 is movable on the rail 600 by means of a nozzle driving part 604 illustrated in FIG. 23. Thus, the cleaning solution nozzle 603 can move from a waiting section 605 provided at the Y-direction positive direction side outer position of the cup 594 to a position above a central portion of the processing target wafer W in the cup 594, and further move in the diameter direction of the processing target wafer W above the processing target wafer W. Further, the arm 601 can freely rise and lower by means of the nozzle driving part 604 to be able to adjust the height of the cleaning solution nozzle 603.

For the cleaning solution nozzle 603, for example, a dual fluid nozzle is used. To the cleaning solution nozzle 603, a supply pipe 610 supplying the cleaning solution to the cleaning solution nozzle 603 is connected as illustrated in FIG. 22. The supply pipe 610 communicates with a cleaning solution supply source 611 storing the cleaning solution therein. Along the supply pipe 610, a supply equipment group 612 is provided which includes a valve, a flow regulator and so on for controlling the flow of the cleaning solution. Further, a supply pipe 613 supplying an inert gas, for example, a nitrogen gas to the cleaning solution nozzle 603 is connected to the cleaning solution nozzle 603. The supply pipe 613 communicates with a gas supply source 614 storing the inert gas therein. Along the supply pipe 613, a supply equipment group 615 is provided which includes a valve, a flow regulator and so on for controlling the flow of the inert gas. Then, the cleaning solution and the inert gas are mixed in the cleaning solution nozzle 603 and supplied from the cleaning solution nozzle 603 to the processing target wafer W. Note that the mixture of the cleaning solution and the inert gas is sometimes referred to simply as a “cleaning solution” hereinafter.

Incidentally, below the porous chuck 590, raising and lowering pins (not illustrated) for supporting the processing target wafer W from below and raising and lowering it may be provided. In this case, the raising and lowering pins pass through through holes (not illustrated) formed in the porous chuck 590 and can project from the upper surface of the porous chuck 590. Then, in place of raising and lowering the porous chuck 590, the raising and lowering pins are raised or lowered to deliver the processing target wafer W to/from the porous chuck 590.

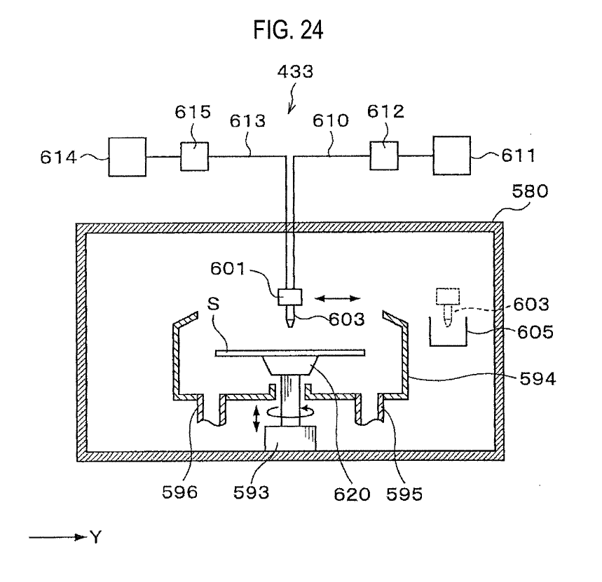

Further, the configuration of the second cleaning unit 433 is substantially the same as the configuration of the above-described first cleaning unit 431. In the second cleaning unit 433, a spin chuck 620 is provided as illustrated in FIG. 24 in place of the porous chuck 590 of the first cleaning unit 431. The spin chuck 620 has a horizontal upper surface, and a suction port (not illustrated) sucking, for example, the supporting wafer S is provided in the upper surface. By suction through the suction port, the supporting wafer S can be suction-held on the spin chuck 620. The other configuration of the second cleaning unit 433 is the same as that of the above-described first cleaning unit 431, and therefore the description thereof is omitted.

Incidentally, in the second cleaning unit 433, a back rinse nozzle (not illustrated) jetting a cleaning solution toward the rear surface of the processing target substrate W, namely, the non joint surface W_{N} may be provided below the spin chuck 620. The cleaning solution jetted from the back rinse nozzle cleans the non-joint surface W_{N} of the processing target wafer W and the outer peripheral portion of the processing target substrate W.

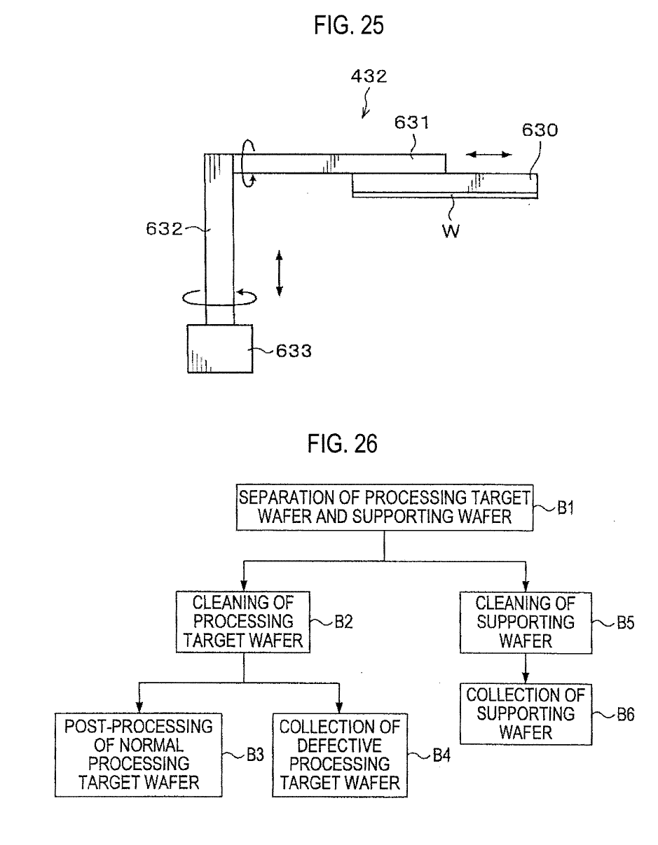

Next, the configuration of the above-described second transfer unit 432 will be described. The second transfer unit 432 has, as illustrated in FIG. 25, a Bernoulli chuck 630 holding the processing target wafer W. The Bernoulli chuck 630 jets air to float the processing target wafer W and thereby can suction-suspend and hold the wafer processing W in a noncontact state. The Bernoulli chuck 630 is supported by a supporting arm 631. The supporting arm 631 is supported by a first driving part 632. By means of the first driving part 632, the supporting arm 631 can turn around the horizontal axis and extend and contract in the horizontal direction. Below the first driving part 632, a second driving part 632 is provided. By means of the second driving part 633, the first driving part 632 can rotate around the vertical axis and rise and lower in the vertical direction.

Note that the third transfer unit 441 has the same configuration as that of the above-described second transfer unit 432, and therefore the description thereof is omitted. However, the second driving part 633 of the third transfer unit 441 is attached to the transfer path 440 illustrated in FIG. 19 so that the third transfer unit 441 is movable on the transfer path 440.

The separation processing method of the processing target wafer W and the supporting wafer S performed using the separation system 400 configured as described above will be described. FIG. 26 is a flowchart illustrating an example, of main steps of the separation processing.

First, a cassette C_{T} housing a plurality of superposed wafers T, an empty cassette C_{W}, and an empty cassette C_{S} are mounted on the predetermined cassette mounting plates 411 of the transfer-in/out station 401. The superposed wafer T in the cassette C_{T} is taken out by the first transfer unit 420 and transferred to the separation unit 430 in the separation processing station 402. In this event, the superposed wafer T is transferred with the processing target wafer W arranged on the upper side and the supporting wafer S arranged on the lower side.

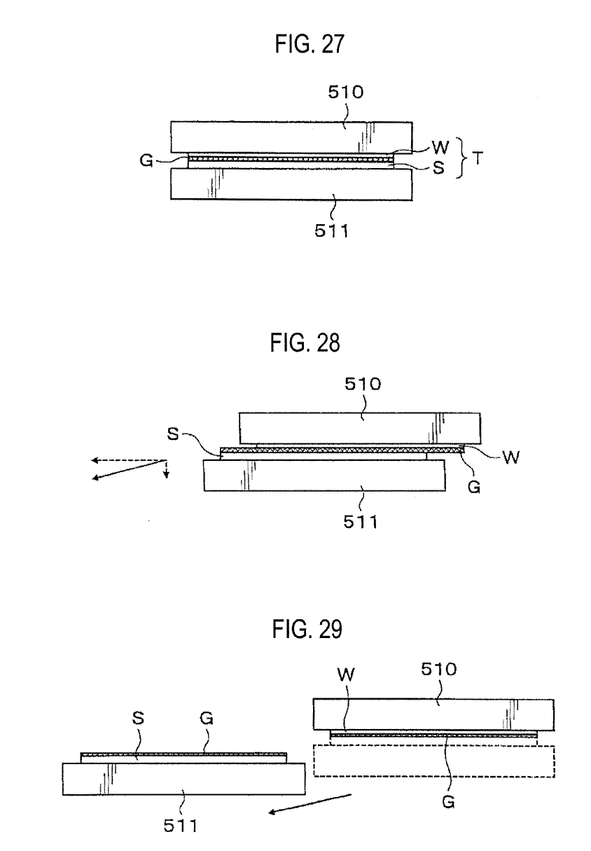

The superposed wafer T transferred in the separation unit 430 is suction-held on the second holding part 511. Thereafter, the second holding part 511 is raised by the moving mechanism 550 so that the superposed wafer T is held sandwiched by the first holding part 510 and the second holding part 511 as illustrated in FIG. 27. In this event, the non-joint surface W_{N} of the processing target wafer W is suction-held by the first holding part 510, and the non-joint surface S_{N} of the supporting wafer S is suction-held by the second holding part 511.

Thereafter, the heating mechanisms 524, 541 heat the superposed wafer T to a predetermine temperature, for example, 200° C. Then, the adhesive G in the superposed wafer T becomes softened.

Subsequently, while the heating mechanisms 524, 541 are heating the superposed wafer T to keep the softened state of the adhesive G, the second holding part 511 and the supporting wafer S are moved by the moving mechanism 550 in the vertical direction and the horizontal direction, namely, an obliquely downward as illustrated in FIG. 28. Then, as illustrated in FIG. 29, the processing target wafer W held by the first holding part 510 and the supporting wafer S held by the second holding part 511 are separated as illustrated in FIG. 29 (Step B1 in FIG. 26).

In this event, the second holding part 511 moves 100 μm in the vertical direction and moves 300 mm in the horizontal direction. Incidentally, in this embodiment, the thickness of the adhesive G in the superposed wafer T is, for example, 30 μm to 40 μm and the height of the electronic circuit (bump) formed on the joint surface W_{J} of the processing target wafer W is, for example, 20 μm. Accordingly, the distance between the electronic circuit on the processing target wafer W and the supporting wafer S is minute. Hence, for example, when the second holding part 511 is moved only in the horizontal direction, the electronic circuit and the supporting wafer S can come into contact, whereby the electronic circuit is susceptible to damage. In this regard, moving the second holding part 511 in the horizontal direction and also in the vertical direction as in this embodiment can prevent the contact between the electronic circuit and the supporting wafer S to suppress damage to the electronic circuit. Note that the ratio between the moving distance in the vertical direction and the moving distance in the horizontal direction of the second holding part 511 is set based on the height of the electronic circuit (bump) on the processing target wafer W.

Thereafter, the processing target wafer W separated in the separation unit 430 is transferred by the second transfer unit 432 to the first cleaning unit 431. Here, the transfer method of the processing target wafer W by the second transfer unit 432 will be described.

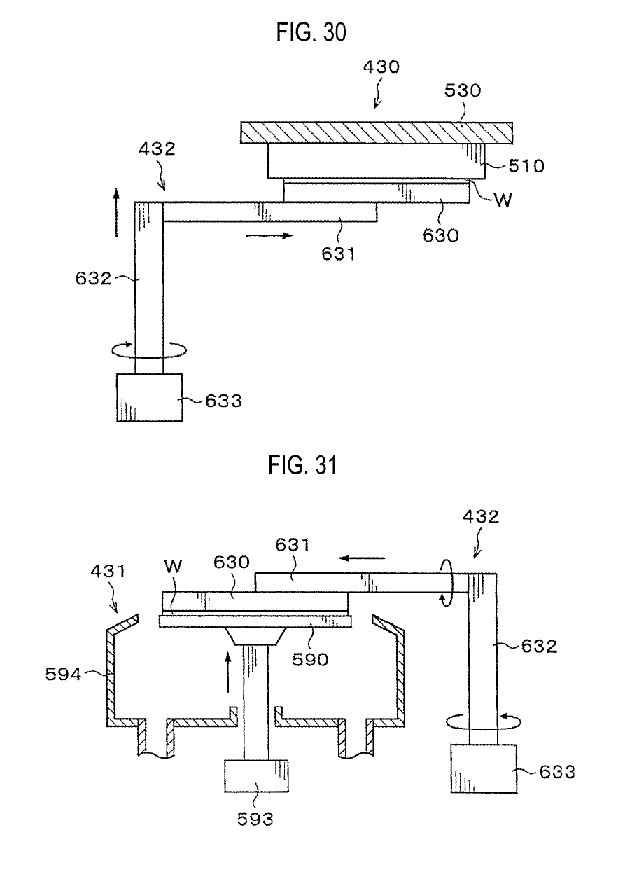

The supporting arm 631 is extended to locate the Bernoulli chuck 630 below the processing target wafer W held by the first holding part 510 as illustrated in FIG. 30. Thereafter, the Bernoulli chuck 630 is raised, and the suction of the processing target wafer W from the suction pipe 523 at the first holding part 510 is stopped. Then, the processing target wafer W is delivered from the first holding part 510 to the Bernoulli chuck 630. In this event, though the joint surface W_{J} of the processing target wafer W is held by the Bernoulli chuck 630, the processing target wafer W is held with the Bernoulli chuck 630 not in contact therewith, so that the electronic circuits on the joint surface W_{J} of the processing target wafer W are never damaged.

Next, as illustrated in FIG. 31, the supporting arm 631 is turned to move the Bernoulli chuck 630 to above the porous chuck 590 in the first cleaning unit 431 and reverse the Bernoulli chuck 630 to thereby direct the processing target wafer W downward. In this event, the porous chuck 590 is raised to a position upper than the cup 594 and kept waiting. Thereafter, the processing target wafer W is delivered from the Bernoulli chuck 630 to the porous chuck 590 and suction-held.

Once the processing target wafer W is suction-held on the porous chuck 590 in this manner, the porous chuck 590 is lowered to a predetermined position. Subsequently, the arm 601 moves the cleaning solution nozzle 603 at the waiting section 605 to a position above the central portion of the processing target wafer W. Thereafter, while the porous chuck 590 is rotating the processing target wafer W, the cleaning solution is supplied to the joint surface W_{J} of the processing target wafer W from the cleaning solution nozzle 603. The supplied cleaning solution is diffused over the entire surface of the joint surface W_{J} of the processing target wafer W by the centrifugal force, whereby the joint surface W_{J} of the processing target wafer W is cleaned (Step B2 in FIG. 26).

Here, the plurality of superposed wafers T transferred in the transfer-in/out station 401 have been subjected to inspection in advance as described above and discriminated between a superposed wafer T including a normal processing target wafer W and a superposed wafer T including a defective processing target wafer W.

The normal processing target wafer W separated from the normal superposed wafer T is cleaned at its joint surface W_{J} at Step B2 and then transferred by the third transfer unit 441 to the post-processing station 403. Note that the transfer of the processing target wafer W by the third transfer unit 441 is substantially the same as the above-described transfer of the processing target wafer W by the second transfer unit 432, and therefore the description thereof is omitted. Thereafter, predetermined post-processing is performed on the processing target wafer W in the post-processing station 403 (Step B3 in FIG. 26). In this manner, the processing target wafer W becomes a product.

On the other hand, the defective processing target wafer W separated from the defective superposed wafer T is cleaned at its joint surface W_{J} at Step B2 and then transferred by the first transfer unit 420 to the transfer-in/out station 401. Thereafter, the defective processing target wafer W is transferred from the transfer-in/out station 401 to the outside and collected (Step B4 in FIG. 26).

While the above-described Steps B2 to B4 are being performed on the processing target wafer W, the supporting wafer S separated in the separation unit 430 is transferred by the first transfer unit 420 to the second cleaning unit 433. Then, in the second cleaning unit 433, the supporting wafer S is cleaned at its joint surface S_{J} (Step B5 in FIG. 26). Note that the cleaning of the supporting wafer S in the second cleaning unit 433 is the same as the above-described cleaning of the processing target wafer W in the first cleaning unit 431, and therefore the description thereof is omitted.

Thereafter, the supporting wafer S whose joint surface S_{J} has been cleaned is transferred by the first transfer unit 420 to the transfer-in/out station 401. Then, the supporting wafer S is transferred from the transfer-in/out station 401 to the outside and collected (Step B6 in FIG. 26). Thus, a series of separation processing of the processing target wafer W and the supporting wafer S ends.

According to the above embodiment, the substrate processing system 350 includes the joint system 1 and the separation system 400, and therefore can concurrently perform the joint processing and the separation processing of the processing target wafer W and the supporting wafer S. Therefore, the throughput of the wafer processing can be improved.

In the separation system 400, after the superposed wafer T is separated into the processing target wafer W and the supporting wafer S in the separation unit 430, the separated processing target wafer W can be cleaned in the first cleaning unit 431 and the separated supporting wafer S can be cleaned in the second cleaning unit 433. As described above, according to this embodiment, a series of separation processing from the separation of the processing target wafer W and the supporting wafer S to the cleaning of the processing target wafer W and the cleaning of the supporting wafer S can be effectively performed in one separation system 400. Further, the cleaning of the processing target wafer W and the cleaning of the supporting wafer S can be concurrently performed in the first cleaning unit 431 and the second cleaning unit 433 respectively. Further, while the processing target wafer W and the supporting wafer S are being separated in the separation unit 430, other processing target wafer W and supporting wafer S can be processed in the first cleaning unit 431 and the second cleaning unit 433. Therefore, it is possible to efficiently perform the separation of the processing target wafer W and the supporting wafer S and thereby improve the throughput of the separation processing.

Further, when the processing target wafer W separated in the separation processing station 402 is the normal processing target wafer W, the processing target wafer W is subjected to the predetermined post-processing into a product in the post-processing station 403. On the other hand, when the processing target wafer W separated in the separation processing station 402 is the defective processing target wafer W, the processing target wafer W is collected from the transfer-in/out station 401. In this manner, only the normal processing target wafer W is made into a product, so that the yield of products can be improved. Further, the defective processing target wafer W is collected and the processing target wafer W can be reused depending on the degree of defects, so that the resource can be effectively used and the manufacturing cost can be reduced.

Further, since the separation of the processing target wafer W and the supporting wafer S to the post-processing of the processing target wafer W can be performed in a series of processes as described above, the throughput of the wafer processing can further be improved.

Further, since the supporting wafer S separated in the separation unit 430 is collected from the transfer-in/out station 401 after cleaning, the supporting wafer S can be reused. Accordingly, the resource can be effectively used and the manufacturing cost can be reduced.

Further, the second transfer unit 432 and the third transfer unit 441 have the Bernoulli chucks 630 holding the processing target wafer W and therefore can appropriately hold the processing target wafer W even though the processing target wafer W has been made thin. Further, though the joint surface W_{J} of the processing target wafer W is held by the Bernoulli chuck 630 in the second transfer unit 432, the processing target wafer W is held with the Bernoulli chuck 630 being not in contact therewith, so that the electronic circuits on the joint surface W_{J} of the processing target wafer W are never damaged.

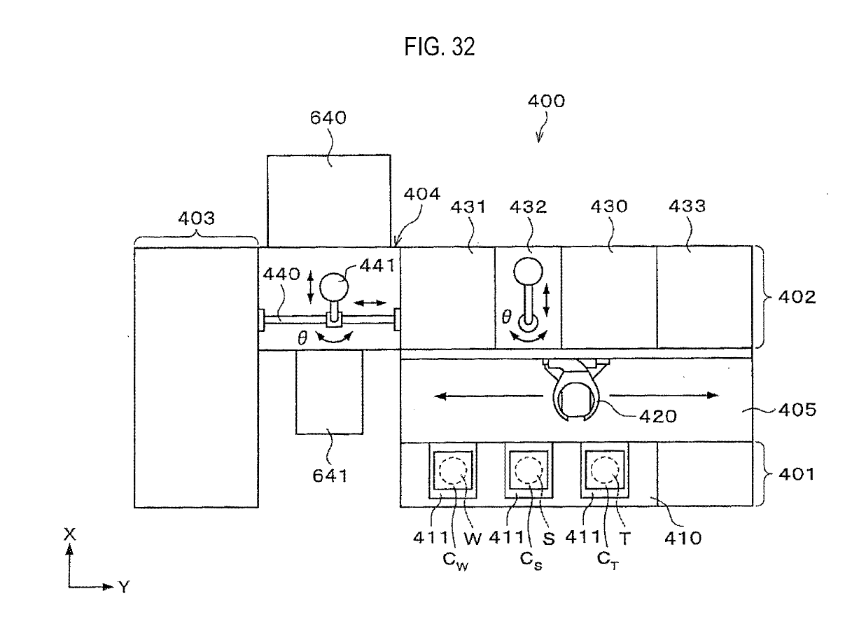

In the separation system 400 of the above-described embodiment, an inspection unit 640 as another inspecting unit inspecting the processing target wafer W separated in the separation processing station 402 may further be provided as illustrated in FIG. 32. The inspection unit 640 is disposed, for example, between the separation processing station 402 and the post-processing station 403. Further, in this case, the transfer path 440 in the interface station 404 is extended in the Y-direction, and the inspection unit 640 is disposed on the X-direction positive direction side of the interface station 404.

Then, in the inspection unit 640, inspection of the front surface (the joint surface W_{J}) of the processing target wafer W is performed. Specifically, the inspection is made, for example, for the damage to the electronic circuits on the processing target wafer W and the residual such as the adhesive G on the processing target wafer W.

Further, a cleaning unit 641 for the processing target wafer W may further be provided on the X-direction negative direction side of the interface station 404 as illustrated in FIG. 32. In this case, when the residual of the adhesive G is found on the processing target wafer W in the inspection unit 640, the processing target wafer W is transferred to the cleaning unit 641 and cleaned.

According to the above embodiment, the processing target wafer W can be inspected in the inspection unit 640, so that the processing conditions in the separation system 400 can be corrected based on the inspection result. Accordingly, it is possible to further appropriately separate the processing target wafer W and the supporting wafer S.

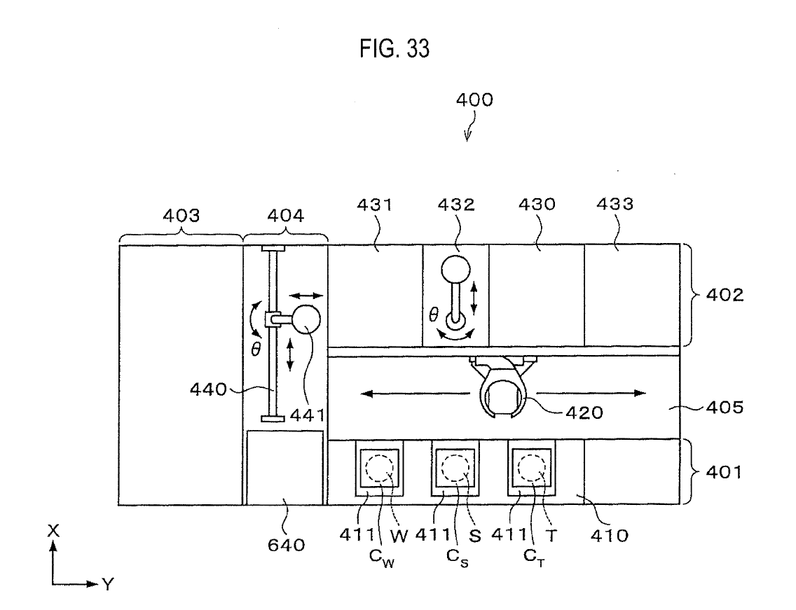

Note that the above-described inspection unit 640 may be provided inside the interface station 404 as illustrated in FIG. 33.

Though the second holding part 511 is moved in the vertical direction and the horizontal direction in the separation unit 430 in the above embodiment, the first holding part 510 may be moved in the vertical direction and the horizontal direction. Alternatively, both the first holding part 510 and the second holding part 511 may be moved in the vertical direction and the horizontal direction.

Though the second holding part 511 is moved in the vertical direction and the horizontal direction in the above separation unit 430, the second holding part 511 may be moved only in the horizontal direction and the moving speed of the second holding part 511 may be changed. Specifically, it is adoptable to set the moving speed at the time of starting to move the second holding part 511 to a low speed and then gradually accelerating the moving speed. In other words, since the contact area between the processing target wafer W and the supporting wafer S is large and the electronic circuits on the processing target wafer W are likely to be affected by the adhesive G at the time of starting to move the second holding part 511, the moving speed of the second holding part 511 is set to a low speed. Thereafter, the electronic circuits on the processing target wafer W become unlikely to be affected by the adhesive G as the contact area between the processing target wafer W and the supporting wafer S becomes smaller, and therefore the moving speed of the second holding part 511 is gradually accelerated. Also in this case, it is possible to prevent the contact between the electronic circuits and the supporting wafer S and suppress the damage to the electronic circuits.

Further, though the second holding part 511 is moved in the vertical direction and the horizontal direction in the separation unit 430 in the above embodiment, the second holding part 511 may be moved only in the horizontal direction, for example, when the distance between the electronic circuits on the processing target wafer W and the supporting wafer S is sufficiently large. In this case, it is possible to prevent the contact between the electronic circuits and the supporting wafer S and it becomes easy to control the movement of the second holding part 511. Further, the second holding part 511 may be moved only in the vertical direction to separate the processing target wafer W and the supporting wafer S, and the outer peripheral end portion of the second holding part 511 may be moved only in the vertical direction to separate the processing target wafer W and the supporting wafer S.

Note that though the processing target wafer W and the supporting wafer S are separated with the processing target wafer W arranged on the upper side and the supporting wafer S arranged on the lower side in the above embodiment, the vertical arrangement of the processing target wafer W and the supporting wafer S may be reversed.

In the second transfer unit 432 in the above embodiment, a plurality of supply ports (not illustrated) for supplying the cleaning solution may be formed in the surface of the Bernoulli chuck 630. In this case, when the processing target wafer W is delivered from the Bernoulli chuck 630 to the porous chuck 590 of the first cleaning unit 431, the cleaning solution can be supplied from the Bernoulli chuck 630 to the joint surface W_{J} of the processing target wafer W to clean the joint surface W_{J} as well as the Bernoulli chuck 630 itself. This can reduce the subsequent cleaning time of the processing target wafer W in the first cleaning unit 431 and further improve the throughput of the separation processing. In addition, the Bernoulli chuck 630 can also be cleaned and therefore can appropriately transfer the next processing target wafer W.

The third transfer unit 441 has the Bernoulli chuck 630 in the above embodiment but may have a porous chuck (not illustrated) in place of the Bernoulli chuck 630. Also in this case, the porous chuck can appropriately suction-hold the thinned processing target wafer W.

Though the dual fluid nozzle is used for the cleaning solution nozzle 603 in the first cleaning unit 431 and the second cleaning unit 433 in the above embodiment, the cleaning solution nozzle 603 is not limited to this embodiment but can adopt various nozzles. For example, as the cleaning solution nozzle 603, a nozzle body in which the nozzle supplying the cleaning solution and the nozzle supplying the inert gas are integrated as one body, a spray nozzle, a jet nozzle, a megasonic nozzle or the like may be used. Further, to improve the throughput of the cleaning processing, a cleaning solution heated, for example, at 80° C. may be supplied.

Further, a nozzle supplying IPA (isopropyl alcohol) may be provided in addition to the cleaning solution nozzle 603 in the first cleaning unit 431 and the second cleaning unit 433. In this case, after the processing target wafer W or the supporting wafer S is cleaned with the cleaning solution from the cleaning solution nozzle 603, the cleaning solution on the processing target wafer W or the supporting wafer S is replaced with IPA. This further surely cleans the joint surface W_{J}, S_{J} of the processing target wafer W or the supporting wafer S.

In the separation system 400 of the above embodiment, a temperature regulator (not illustrated) cooling the processing target wafer W, which has been heated in the separation unit 430, to a predetermined temperature may be provided. In this case, since the temperature of the processing target wafer W is regulated to an appropriate temperature, the processing subsequent thereto can be more smoothly performed.

Further, though the case where the post-processing is performed on the processing target wafer W in the post-processing station 403 has been described in the above embodiment, the present disclosure is also applicable to the case where a processing target wafer used in the three-dimensional integration technique is separated from a supporting wafer. Note that the three-dimensional integration technique is the technique responding to the demand for higher integration of semiconductor devices in recent years in which a plurality of highly integrated semiconductor devices are three-dimensionally stacked instead of arrangement of the highly integrated semiconductor devices within a horizontal surface. Also in this three-dimensional integration technique, reduction in thickness of the processing target wafers to be stacked is required, and the processing target wafer is joined with the supporting wafer and subjected to the predetermined processing.

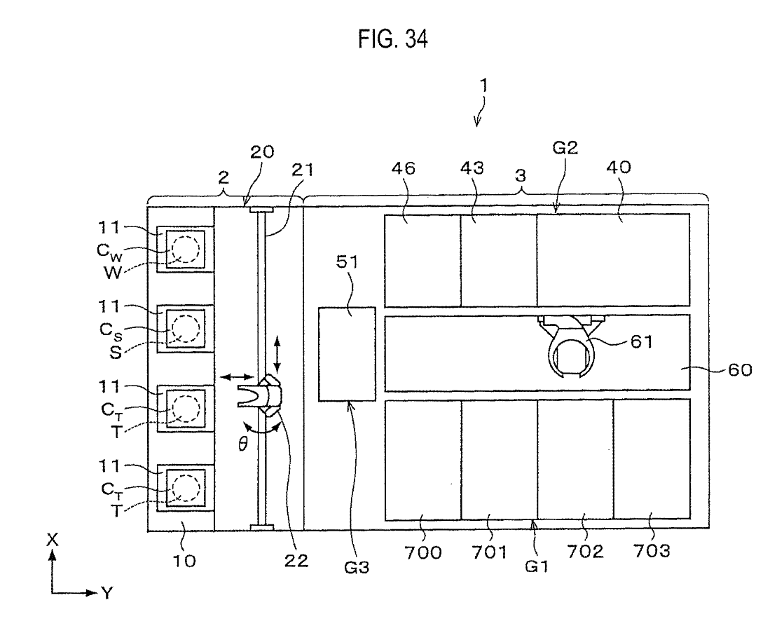

Next, the configurations of the joint units 30 to 33 and the reversing units 34 to 37 in the joint system 1 in the above embodiment will be described in more detail. In this embodiment, the reversing unit 34 is provided integrally with the joint unit 30 in the joint unit 30, and a joint unit 700 is disposed in the joint system 1 as illustrated in FIG. 34. Similarly, the joint units 31 to 33 and the reversing unit 35 to 37 are integrally formed to constitute joint units 701 to 703 respectively. In addition, the joint units 701 to 703 are provided in the first processing block G1 and arranged side by side in the Y-direction in this order from the transfer-in/out station 2 side. Note that a case of joining the processing target wafer W and the supporting wafer S together with the processing target wafer W arranged on the lower side and the supporting wafer arranged on the upper side will be described in this embodiment.

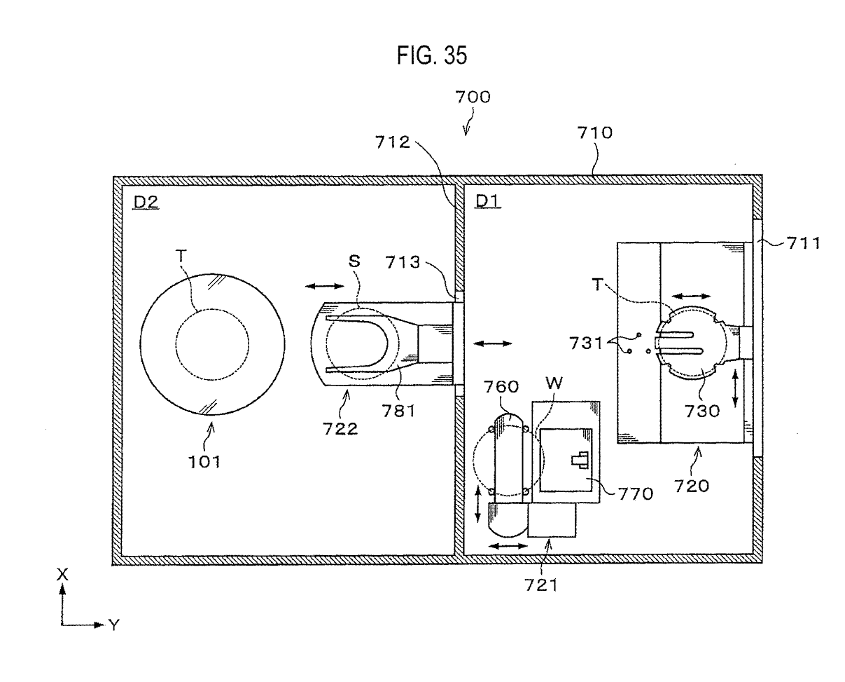

The joint unit 700 has a processing container 710 hermetically closable the inside thereof as illustrated in FIG. 35. In the side surface on the wafer transfer region 60 side of the processing container 710, a transfer-in/out port 711 for the processing target wafer W, the supporting wafer S, and the superposed wafer T is formed, and an opening/closing shutter (not illustrated) is provided at the transfer-in/out port.

The inside of the processing container 710 is partitioned by an inner wall 712 into a pre-processing region D1 and a joining region D2. The above-described transfer-in/out port 711 is formed in the side surface of the processing container 710 in the pre-processing region D1. Further, also in the inner wall 712, a transfer-in/out port 713 for the processing target wafer W, the supporting wafer S, and the superposed wafer T is formed. Note that in this embodiment, the pre-processing region D1 corresponds to the reversing unit 34 in the above-described embodiment and the joining region D2 corresponds to the joint unit 30 in the above-described embodiment.

On a Y-direction positive direction side of the pre-processing region D1, delivery parts 720 for delivering the processing target wafer W, the supporting wafer S, and the superposed wafer T to/from the outside of the joint unit 700 are provided. The delivery parts 720 are disposed adjacent to the transfer-in/out port 711. Further, the delivery parts 720 are arranged at a plurality of tiers, for example, two tiers in the vertical direction and can concurrently delivery two of the processing target wafer W, the supporting wafer S, and the superposed wafer T. For example, one delivery part 720 may deliver the processing target wafer W or the supporting wafer S before joining and the other delivery part 720 may delivery the superposed wafer T after joining. Alternatively, one delivery part 720 may deliver the processing target wafer W before joining and the other delivery part 720 may delivery the supporting wafer S before joining.

On a Y-direction negative direction side, namely, on the transfer-in/out port 713 side in the pre-processing region D1, for example, a reversing part 721 reversing the front and rear surfaces of the supporting wafer S is provided. Note that the reversing part 721 can also adjust the orientation in the horizontal direction of the supporting wafer S and can also adjust the orientation in the horizontal direction of the processing target wafer W as will be described later.

On a Y-direction positive direction side in the joining region D2, a transfer part 722 transferring the processing target wafer W, the supporting wafer S, and the superposed wafer T to the delivery part 720, the reversing part 721, and the joint part 101 is provided. The transfer part 722 is attached to the transfer-in/out port 713.

On a Y-direction negative direction side in the joining region D2, the joint part 101 joining the processing target wafer W and the supporting wafer S together via the adhesive G by pressing them is provided. The configuration of the joint part 101 is the same as the configuration of the joint part 101 in the above embodiment, and therefore the description thereof is omitted.

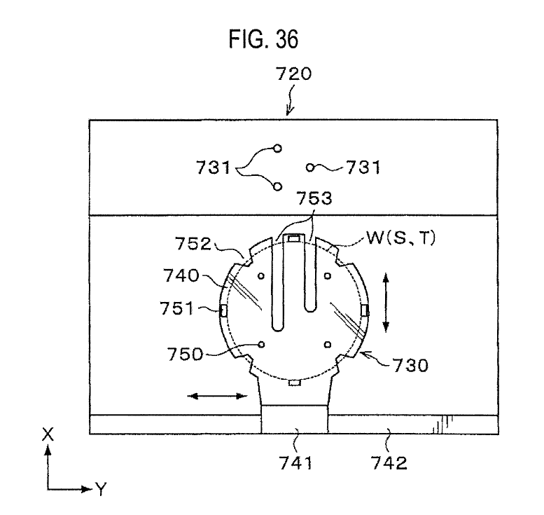

Next, the configuration of the above-described delivery part 720 will be described. The delivery part 720 has a delivery arm 730 and wafer supporting pins 731 as illustrated in FIG. 36. The delivery arm 730 can delivery the processing target wafer W, the supporting wafer S, the superposed wafer T between the outside of the joint unit 700, namely, the wafer transfer unit 61 and the wafer supporting pins 731. The wafer supporting pins 731 are provided at a plurality of, for example, three locations and can support the processing target wafer W, the supporting wafer S, the superposed wafer T.

The delivery arm 730 has an arm part 740 holding the processing target wafer W, the supporting wafer S, the superposed wafer T and an arm driving part 741 equipped with, for example, a motor. The arm part 740 has an almost disk shape. The arm driving part 741 can move the arm part 740 in the X-direction (a top-down direction in FIG. 36). Further, the arm driving part 741 is attached on a rail 742 extending in the Y-direction (a right-left direction in FIG. 36) and configured to be movable on the rail 742. With this configuration, the delivery arm 730 can move in the horizontal directions (the X-direction, the Y-direction) and smoothly delivery the processing target wafer W, the supporting wafer S, the superposed wafer T between the wafer transfer unit 61 and the wafer supporting pins 731.

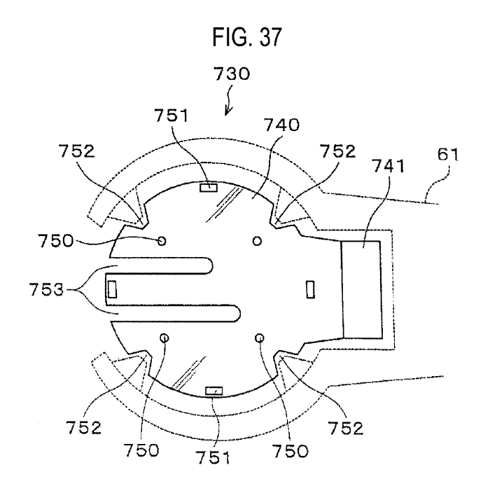

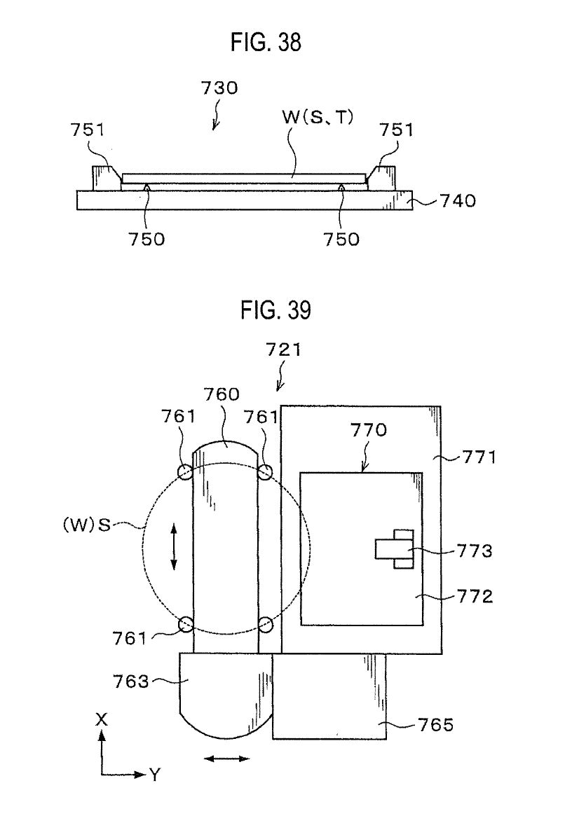

On the arm part 740, wafer supporting pins 750 supporting the processing target wafer W, the supporting wafer S, the superposed wafer T are provided at a plurality of, for example, four locations as illustrated in FIG. 37 and FIG. 38. Further, on the arm part 740, guides 751 positioning the processing target wafer W, the supporting wafer S, the superposed wafer T supported on the wafer supporting pins 750 are provided. The guides 751 are provided at a plurality of, for example, four locations in a manner to guide the side surface of the processing target wafer W, the supporting wafer S, the superposed wafer T.

At the outer periphery of the arm part 740, cutouts 752 are provided at, for example, four locations as illustrated in FIG. 36 and FIG. 37. The cutouts 752 make it possible to prevent the transfer arm of the wafer transfer unit 61 from interfering with the arm part 740 when the processing target wafer W, the supporting wafer S, the superposed wafer T is delivered from the transfer arm of the wafer transfer unit 61 to the delivery arm 730.

In the arm part 740, two slits 753 are formed along the X-direction. The slits 753 are formed from the end face on the wafer supporting pins 731 side of the arm part 740 to the vicinity of the middle portion of the arm part 740. The slits 753 make it possible to prevent the arm part 740 from interfering with the wafer supporting pins 731.

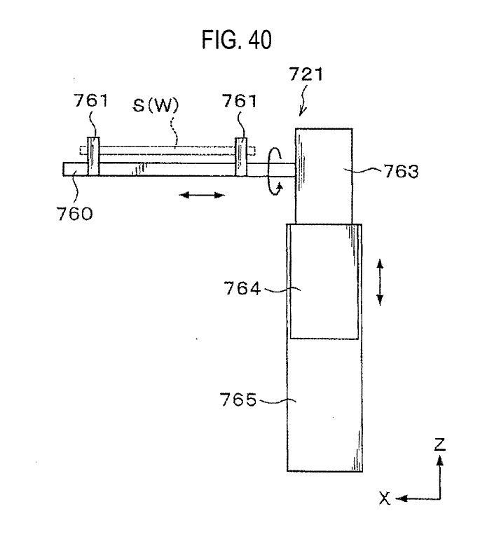

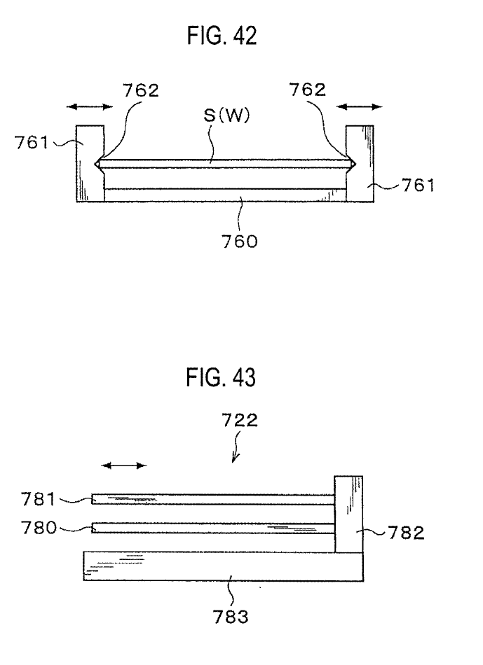

Next, the configuration of the above-described reversing part 721 will be described. The reversing part 721 has a holding arm 760 holding the supporting wafer S, the processing target wafer W as illustrated in FIG. 39 to FIG. 41. The holding arm 760 extends in the horizontal direction (the X-direction in FIG. 39 and FIG. 40). Further, on the holding arm 760, holding members 761 as other holding members holding the supporting wafer S, the processing target wafer W are provided at, for example, four locations. The holding members 761 are configured to be movable in the horizontal direction with respect to the holding arm 760 as illustrated in FIG. 42. In the side surfaces of the holding members 761, cutouts 762 for holding the outer peripheral portion of the supporting wafer S, the processing target wafer W are formed. These holding members 761 can hold the supporting wafer S, the processing target wafer W sandwiched between them.

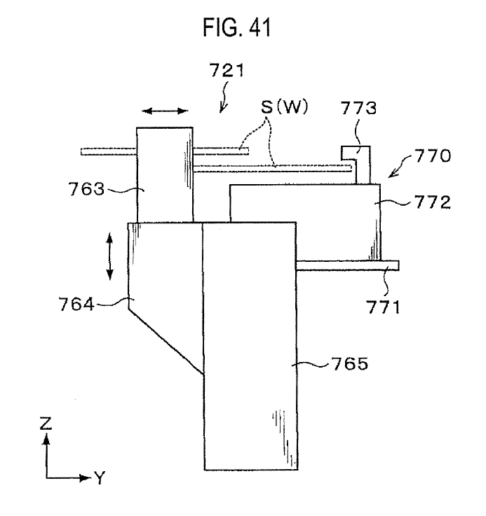

The holding arm 760 is supported by a first driving part 763 equipped with, for example, a motor as illustrated in FIG. 39 to FIG. 41. By means of the first driving part 763, the holding arm 760 can freely turn around the horizontal axis and move in the horizontal direction (the X-direction in FIG. 39 and FIG. 40 and in the Y-direction in FIG. 39 and FIG. 41). Note that the first driving part 763 may turn the holding arm 760 around the vertical axis and move the holding arm 760 in the horizontal direction. Below the first driving part 763, a second driving part 764 equipped with, for example, a motor is provided. By means of the second driving part 764, the first driving part 763 can move in the vertical direction along a supporting post 765 extending in the vertical direction. As described above, the supporting wafer S, the processing target wafer W held by the holding members 761 can be turned around the horizontal axis and moved in the vertical direction and the horizontal direction by the first driving part 763 and the second driving part 764. Note that the first driving part 763 and the second driving part 764 constitute the moving mechanism of the present disclosure.

On the supporting post 765, a position adjusting mechanism 770 adjusting the orientation in the horizontal direction of the supporting wafer S, the processing target wafer W held by the holding members 761 is supported via a supporting plate 771. The position adjusting mechanism 770 is provided adjacent to the holding arm 760.

The position adjusting mechanism 770 has a transfer part 722 and a detection part 773 detecting the position of the notch portion of the supporting wafer S, the processing target wafer W. Then, in the position adjusting mechanism 770, the position of the notch portion of the supporting wafer S, the processing target wafer W is detected by the detection part 773 while the supporting wafer S, the processing target wafer W held by the holding members 761 is being moved in the horizontal direction, whereby the position of the notch portion is adjusted to adjust the orientation in the horizontal direction of the supporting wafer S, the processing target wafer W.

Next, the configuration of the above-described transfer part 722 will be described. The transfer part 722 has a plurality of, for example, two transfer arms 780, 781 as illustrated in FIG. 43. The first transfer arm 780 and the second transfer arm 781 are arranged in this order from the bottom in the vertical direction. Note that the first transfer arm 780 and the second transfer arm 781 have different shapes as will be described later.

At the base end portions of the transfer arms 780, 781, an arm driving part 782 equipped with, for example, a motor is provided. By means of this arm driving part 782, each of the transfer arms 780, 781 can independently move in the horizontal direction. The transfer arms 780, 781 and the arm driving part 782 are supported on a base 783.

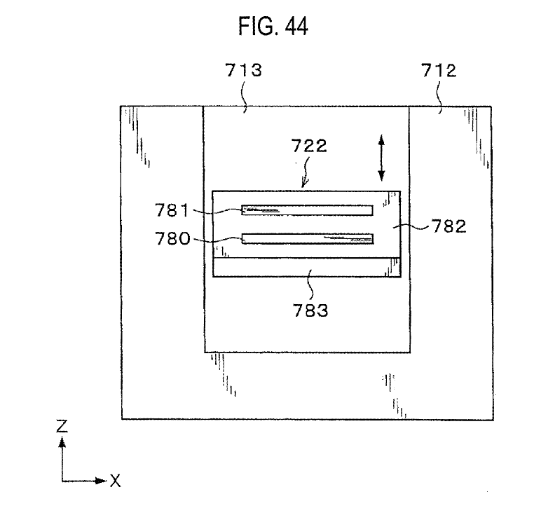

The transfer part 722 is provided at the transfer-in/out port 713 formed in the inner wall 712 of the processing container 710 as illustrated in FIG. 35 and FIG. 44. The transfer part 722 can move in the vertical direction along the transfer-in/out port 713 by means of a driving part (not illustrated) equipped with, for example, a motor.

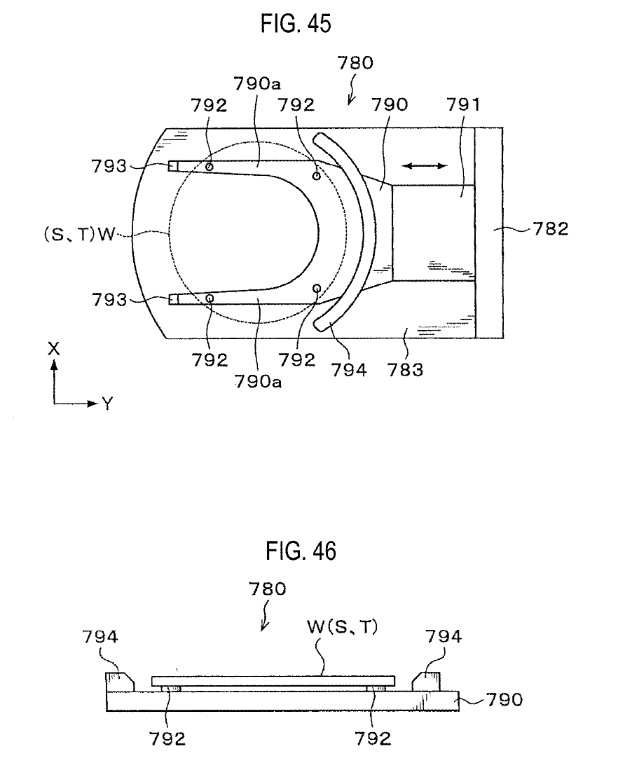

The first transfer arm 780 transfers the processing target wafer W, the supporting wafer S, the superposed wafer T while holding the rear surface thereof (the non-joint surface W_{N}, S_{N} in the processing target wafer W, the supporting wafer S). The first transfer arm 780 has an arm part 790 having a tip branched off into two tip end portions 790a, 790a, and a supporting part 791 integrally formed with the arm part 790 and supporting the arm part 790 as illustrated in FIG. 45.

On the arm part 790, O-rings 792 made of resin as first holding members are provided at a plurality of, for example, four locations as illustrated in FIG. 45 and FIG. 46. The O-rings 792 come into contact with the rear surface of the processing target wafer W, the supporting wafer S, the superposed wafer T, and the O-rings 792 hold the rear surface of the processing target wafer W, the supporting wafer S, the superposed wafer T by the friction force between the O-rings 792 and the rear surface of the processing target wafer W, the supporting wafer S, the superposed wafer T. The first transfer arm 780 can horizontally hold the processing target wafer W, the supporting wafer S, the superposed wafer T on the O-rings 792.

Further, on the arm part 790, guide members 793, 794 provided outside the processing target wafer W, the supporting wafer S, the superposed wafer T held on the O-rings 792 are provided. The first guide members 793 are provided at the tips of the tip end portions 790a of the arm part 790. The second guide member 794 is formed in an arc shape along the outer periphery of the processing target wafer W, the supporting wafer S, the superposed wafer T and provided on the supporting part 791 side. The guide members 793, 794 can prevent the processing target wafer W, the supporting wafer S, the superposed wafer T from protruding from or slipping off the first transfer arm 780. Note that when the processing target wafer W, the supporting wafer S, the superposed wafer T is held at an appropriate position on the O-rings 792, the processing target wafer W, the supporting wafer S, the superposed wafer T never comes into contact with the guide members 793, 794.

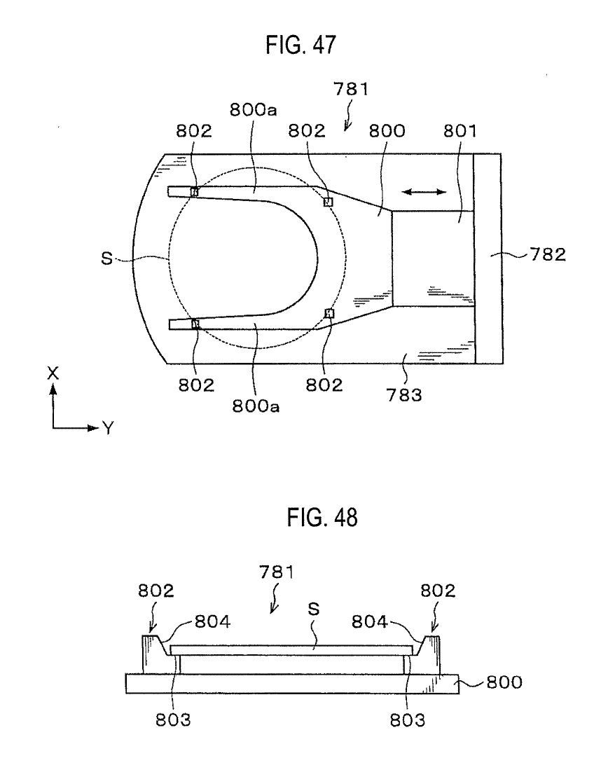

The second transfer arm 781 transfers the supporting wafer S while holding the outer peripheral portion of the front surface thereof, namely, the joint surface S_{J}. More specifically, the second transfer arm 781 transfers the supporting wafer S while holding the outer peripheral portion of the joint surface S_{J} of the supporting wafer S whose front and rear surfaces have been reversed by the reversing part 721. The second transfer arm 781 has an arm part 800 having a tip branched off into two tip end portions 800a, 800a, and a supporting part 801 integrally formed with the arm part 800 and supporting the arm part 800 as illustrated in FIG. 47.

On the arm part 800, second holding members 802 are provided at a plurality of, for example, four locations as illustrated in FIG. 47 and FIG. 48. The second holding member 802 has a mounting part 803 for mounting the outer peripheral portion of the joint surface S_{J} of the supporting wafer S and a tapered part 804 extending upward from the mounting part 803 and having an inner side surface expanding in a tapered shape from the lower side to the upper side. The mounting part 803 holds the outer peripheral portion, for example, within 1 mm from the edge of the supporting wafer S. Further, since the inner side surface of the tapered part 804 expands in a tapered shape from the lower side to the upper side, the supporting wafer S can be smoothly guided by the tapered part 804 and positioned and held on the mounting part 803 even if the supporting wafer S delivered to the second holding member 802 is displaced in the horizontal direction from a predetermined position. The second transfer arm 781 can horizontally hold the supporting wafer S on the second holding members 802.

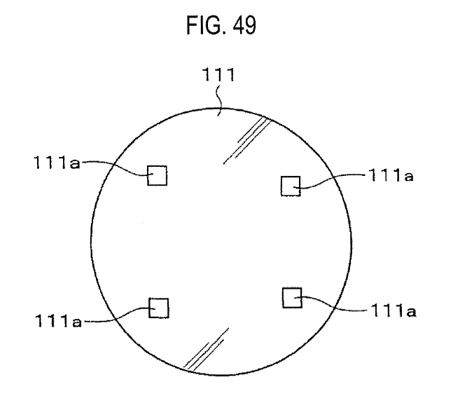

Note that cutouts 111a are formed at, for example, four locations in the second holding part 111 of the joint part 101 as illustrated in FIG. 49. The cutouts 111a make it possible to prevent the second holding members 802 of the second transfer arm 781 from interfering with the second holding part 111 when the supporting wafer S is delivered from the second transfer arm 781 to the second holding part 111.

Note that the configurations of the joint units 701 to 703 are the same as the configuration of the above-described joint unit 700, and therefore the description thereof is omitted.

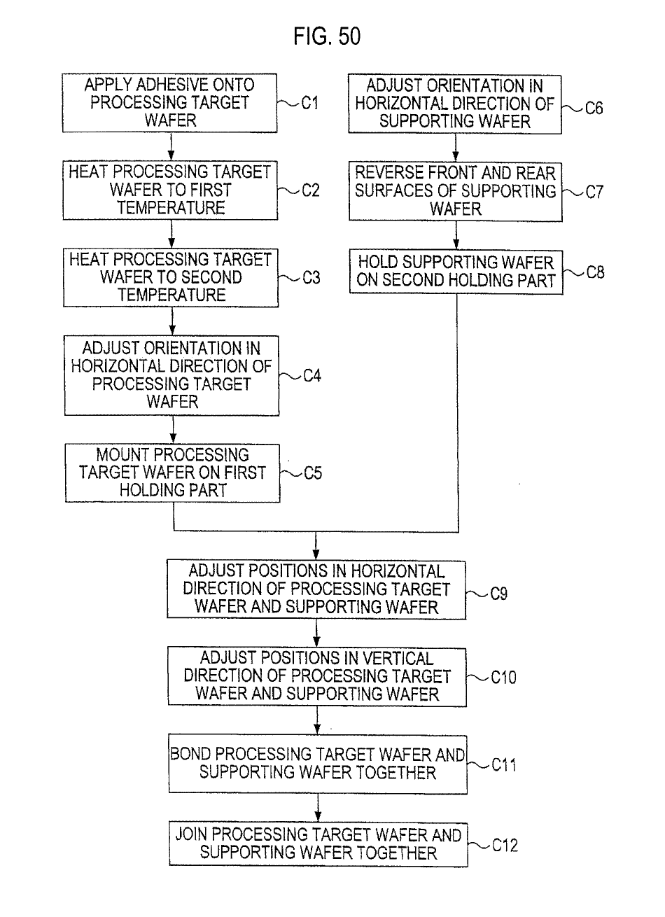

The joint units 700 to 703 according to this embodiment are configured as described above. Next, the joint processing method of the processing target wafer W and the supporting wafer S performed in the joint system 1 including the joint units 700 to 703 will be described. FIG. 50 is a flowchart illustrating an example of main steps of the joint processing.

First, an adhesive G is applied to the joint surface W_{J} of the processing target wafer W (Step C1 in FIG. 50). Thereafter, the processing target wafer W is heated to the first temperature in the first heat processing unit 41 (Step C2 in FIG. 50), and then heated to the second temperature in the second heat processing unit 44 (Step C3 in FIG. 50). Thereafter, the processing target wafer W is transferred to the joint unit 700. Note that these Steps C1 to C3 are the same as Steps A1 to A3 in the above embodiment, and therefore the description thereof is omitted.

The processing target wafer W transferred to the joint unit 700 is delivered from the wafer transfer unit 61 to the delivery arm 730 of the delivery part 720 and then further delivered from the delivery arm 730 to the wafer supporting pins 731. Thereafter, the processing target wafer W is transferred by the first transfer arm 780 in the transfer part 722 from the wafer supporting pins 731 to the reversing part 721.

The processing target wafer W transferred to the reversing part 721 is held by the holding member 761 and moved to the position adjusting mechanism 770. Then, in the position adjusting mechanism 770, the position of the notch portion of the processing target wafer W is adjusted to adjust the orientation in the horizontal direction of the processing target wafer W (Step C4 in FIG. 50).

Thereafter, the processing target wafer W is transferred by the first transfer arm 780 of the transfer part 722 from the reversing part 721 to the joint part 101. The processing target wafer W transferred to the joint part 101 is mounted on the first holding part 110 (Step C5 in FIG. 50). On the first holding part 110, the processing target wafer W is mounted with the joint surface W_{J} of the processing target wafer W facing upward, namely, the adhesive G facing upward.

During the time when the above-described processing at Step C1 to C5 is performed on the processing target wafer W, the supporting wafer S is subjected to processing subsequently to the processing target wafer W. The supporting wafer S is transferred by the wafer transfer unit 61 to the joint unit 700. Note that the step of transferring the supporting wafer S to the joint unit 700 is the same as that in the above embodiment, and the description thereof is omitted.

The supporting wafer S transferred to the joint unit 700 is delivered from the wafer transfer unit 61 to the delivery arm 730 of the delivery part 720, and then delivered from the delivery arm 730 to the wafer supporting pins 731. Thereafter, the supporting wafer S is transferred by the first transfer arm 780 of the transfer part 722 from the wafer supporting pins 731 to the reversing part 721.

The supporting wafer S transferred to the reversing part 721 is held by the holding member 761 and moved to the position adjusting mechanism 770. Then, in the position adjusting mechanism 770, the position of the notch portion of the supporting wafer S is adjusted to adjust the orientation in the horizontal direction of the supporting wafer S (Step C6 in FIG. 50). The supporting wafer S whose orientation in the horizontal direction has been adjusted is moved in the horizontal direction from the position adjusting mechanism 770 and moved upward in the vertical direction, and then the front and rear surfaces thereof are reversed (Step C7 in FIG. 50). In short, the joint surface S_{J} of the supporting wafer S is directed downward.

Thereafter, the supporting wafer S is moved downward in the vertical direction and then transferred by the second transfer arm 781 of the transfer part 722 from the reversing part 721 to the joint part 101. In this event, the second transfer arm 781 holds only the outer peripheral portion of the joint surface S_{J} of the supporting wafer S, so that the joint surface S_{J} is never contaminated with, for example, particles adhering to the second transfer arm 781. The supporting wafer S transferred to the joint part 101 is suction-held on the second holding part 111 (Step C8 in FIG. 50). In the second holding part 111, the supporting wafer S is held with the joint surface S_{J} of the supporting wafer S facing downward.

Thereafter, the positions in the horizontal direction of the processing target wafer W and the supporting wafer S are adjusted (Step C9 in FIG. 50) and the positions in the vertical direction of the processing target wafer W and the supporting wafer S are adjusted (Step C10 in FIG. 50). Thereafter, the processing target wafer W and the supporting wafer S are bonded together with the adhesive G (Step C11 in FIG. 50), and the processing target wafer W and the supporting wafer S are pressed to be firmly joined together (Step C12 in FIG. 50). Note that these Steps C9 to C12 are the same as Steps A7 to A10 in the above embodiment, and therefore the description thereof is omitted.

The superposed wafer T made by joining the processing target wafer W and the supporting wafer S is transferred by the first transfer arm 780 of the transfer part 722 from the joint part 101 to the delivery part 720. The superposed wafer T transferred to the delivery part 720 is delivered to the delivery arm 730 via the wafer supporting pins 731, and further delivered from the delivery arm 730 to the wafer transfer unit 61. Thereafter, the superposed wafer T is transferred by the wafer transfer unit 61 to the transition unit 51 and then transferred by the wafer transfer unit 22 in the transfer-in/out station 2 to the cassette C_{T} on the predetermined cassette mounting plate 11. Thus, a series of joint processing of the processing target wafer W and the supporting wafer S ends.

When the above-described bond unit of Patent Document 1 is used here, the front and rear surfaces of the wafer need to be reversed outside the bond unit. In this case, since the wafer needs to be transferred to the bond unit after the front and rear surfaces are reversed, there is room to improve the throughput of the whole joint processing. Further, once the front and rear surfaces of the wafer are reversed, the joint surface of the wafer faces downward. In this case, when using an ordinary transfer unit holding the rear surface of the wafer, the joint surface of the wafer will be held on the transfer unit, so that, for example, if particles and so on adhere to the transfer unit, the particles can adhere to the joint surface of the wafer. Further, the bond unit of Patent Document 1 does not include the function of adjusting the orientations in the horizontal direction of the wafer and the supporting substrate, so that the wafer and the supporting substrate can be joined displaced from each other.

In this regard, according to this embodiment, since both the reversing part 721 and the joint part 101 are provided in the joint unit 700, the supporting wafer S can be transferred by the transfer part 722 to the joint part 101 immediately after the supporting wafer S is reversed. Since both the reversal of the supporting wafer S and the joining of the processing target wafer W and the supporting wafer S are performed in one joint unit 700 as described above, the joining of the processing target wafer W and the supporting wafer S can be efficiently performed. Accordingly, the throughput of the joint processing can further be improved.

Further, since the second transfer arm 781 of the transfer part 722 holds the outer peripheral portion of the joint surface S_{J} of the supporting wafer S, the joint surface S_{J} is never contaminated with the particles and the like adhering, for example, to the second transfer arm 781. Further, the first transfer arm 780 of the transfer part 722 transfers the processing target wafer W, the supporting wafer S, the superposed wafer T while holding the non-joint surface W_{N}, the joint surface S_{J}, the rear surface, respectively. The transfer part 722 includes two kinds of transfer arms 780, 781 as described above and therefore can efficiently transfer the processing target wafer W, the supporting wafer S, the superposed wafer T.

Further, since the inner side surface of the tapered part 804 of the second holding member 802 expands in a tapered shape from the lower side to the upper side in the second transfer arm 781, the tapered parts 804 can smoothly guide the supporting wafer S to position it, for example, even if the supporting wafer S to be delivered to the second holding member 802 is displaced from a predetermined position in the horizontal direction.

Further, the guide members 793, 794 are provided on the arm part 790 in the first transfer arm 780 and therefore can prevent the processing target wafer W, the supporting wafer S, the superposed wafer T from protruding from or slipping off the first transfer arm 780.

Further, the reversing part 721 can reverse the front and rear surfaces of the supporting wafer S by the first driving part 763 and adjust the orientations in the horizontal direction of the supporting wafer S and the processing target wafer W by the position adjusting mechanism 770. Accordingly, the supporting wafer S and the processing target wafer W can be appropriately joined together in the joint part 101. Further, since the reversal of the supporting wafer S and the adjustment of the orientations in the horizontal direction of the supporting wafer S and the processing target wafer W are performed in one reversing part 721 in the joint part 101, the joining of the processing target wafer W and the supporting wafer S can be efficiently performed. Accordingly, the throughput of the joint processing can further be improved.

Further, the delivery parts 720 are two-tiered in the vertical direction and therefore can concurrently deliver two of the processing target wafer W, the supporting wafer S, and the superposed wafer T. Accordingly, the processing target wafer W, the supporting wafer S, and the superposed wafer T can be efficiently delivered to/from the outside of the joint unit 700, and the throughput of the joint processing can further be improved.

Note that though the processing target wafer W and the supporting wafer S are joined together with the processing target wafer W arranged on the lower side and the supporting wafer S arranged on the upper side in the above embodiment, the vertical arrangement of the processing target wafer W and the supporting wafer S may be reversed. In this case, after the above-described Steps C1 to C5 are performed on the supporting wafer S and the adhesive G is applied on the joint surface S_{J} of the supporting wafer S and heated, the orientation in the horizontal direction of the supporting wafer S is adjusted. Further, after the above-described Steps C6 to C8 are performed on the processing target wafer W and the orientation in the horizontal direction of the processing target wafer W is adjusted, the front and rear surfaces of the processing target wafer W are reversed. Then, the above-described Steps C9 to C12 are performed to join the supporting wafer S and the processing target wafer W together.

The first transfer arm 780 of the transfer part 722 has the O-rings 792 for holding the processing target wafer W, the supporting wafer S, the superposed wafer T in the above embodiment, but the present disclosure is not limited to this configuration. For example, the first holding member only needs to generate the friction force between the first holding member and the rear surface of the processing target wafer W, the supporting wafer S, the superposed wafer T, and may have other suction pads and the like in place of the O-rings 792.

Note that the transfer part 722 may be omitted from the joint unit 700 in the above embodiment. In this case, by moving the holding arm 760 of the reversing part 721, the processing target wafer W, the supporting wafer S is delivered between the delivery part 720 and the reversing part 721, and the processing target wafer W, the supporting wafer S is delivered between the reversing part 721 and the joint part 101. In the joint unit 700 from which the transfer part 722 is omitted as described above, the reversal and the adjustment in the horizontal direction of the processing target wafer W, the supporting wafer S as well as the transfer of the processing target wafer W, the supporting wafer S are performed in the reversing part 721, resulting in a reduced throughput of the joint processing as compared to the above embodiment. However, for example, when a high throughput is not required in the joint processing of the processing target wafer W and the supporting wafer S, the use of the joint unit 700 from which the transfer part 722 is omitted is useful because the apparatus configuration is simplified.

Note that the inventors suggest the following joint unit in addition to the above embodiment. That is a joint unit joining a processing target substrate and a supporting substrate together, including: a delivery part for delivering the processing target substrate, the supporting substrate or the superposed substrate to/from an outside of the joint unit; a reversing part reversing the front and rear surfaces of the supporting substrate to be joined with the processing target substrate coated with the adhesive or the processing target substrate to be joined with the supporting substrate coated with the adhesive; a joint part joining the processing target substrate and the supporting substrate together via the adhesive by pressing the processing target substrate and the supporting substrate; and a transfer part transferring the processing target substrate, the supporting substrate or the superposed substrate to the delivery part, the reversing part, and the joint part, wherein the transfer part includes; a first transfer arm including a first holding member holding the rear surface of the processing target substrate, the supporting substrate or the superposed substrate; and a second transfer arm including a second holding member holding an outer peripheral portion of the front surface of the processing target substrate or the supporting substrate, and wherein the second holding member includes a mounting part mounting the outer peripheral portion of the front surface of the processing target substrate or the supporting substrate, and a tapered part extending upward from the mounting part and having an inner side surface expanding in a tapered shape from a lower side to an upper side.

In this case, the first transfer arm may include a guide member provided outside the processing target substrate, the supporting substrate or the superposed substrate held by the first holding member. Further, the first holding member may hold the processing target substrate, the supporting substrate or the superposed substrate by a friction force.

The inventors further suggest the following joint method. That is a joint method of joining a processing target substrate and a supporting substrate together using a joint unit, wherein the joint unit includes: a delivery part for delivering the processing target substrate, the supporting substrate or the superposed substrate to/from an outside of the joint unit; a reversing part reversing front and rear surfaces of the supporting substrate to be joined with the processing target substrate coated with the adhesive or the processing target substrate to be joined with the supporting substrate coated with the adhesive; a joint part joining the processing target substrate and the supporting substrate together via the adhesive by pressing the processing target substrate and the supporting substrate; and a transfer part transferring the processing target substrate, the supporting substrate or the superposed substrate to the delivery part, the reversing part, and the joint part, wherein the transfer part includes: a first transfer arm including a first holding member holding the rear surface of the processing target substrate, the supporting substrate or the superposed substrate; and a second transfer arm including a second holding member holding an outer peripheral portion of the front surface of the processing target substrate or the supporting substrate, wherein the second holding member includes a mounting part mounting the outer peripheral portion of the front surface of the processing target substrate or the supporting substrate, and a tapered part extending upward from the mounting part and having an inner side surface expanding in a tapered shape from a lower side to an upper side. Further, the joint method includes: a reversing step of transferring the supporting substrate to be joined with the processing target substrate coated with the adhesive or the processing target substrate to be joined with the supporting substrate coated with the adhesive by the transfer part from the delivery part to the reversing part, and reversing the front and rear surfaces of the supporting substrate or the processing target substrate in the reversing part; and a joint step of then transferring the processing target substrate or the supporting substrate by the transfer part from the reversing part to the joint part, and joining, in the joint part, the processing target substrate or the supporting substrate coated with the adhesive with the supporting substrate or the processing target substrate whose front and rear surfaces have been reversed in the reversing part, wherein in the joint step, the supporting substrate or the processing target substrate whose front and rear surfaces have been reversed in the reversing part is transferred by the second transfer arm to the joint part, and wherein in the joint step, the processing target substrate or the supporting substrate whose front and rear surfaces have not been reversed in the reversing part is transferred by the first transfer arm to the joint part.

As still another joint unit, the inventors suggest the following one. That is a joint unit joining a processing target substrate and a supporting substrate together, including: a delivery part for delivering the processing target substrate, the supporting substrate or the superposed substrate to/from an outside of the joint unit; a reversing part reversing the front and rear surfaces of the supporting substrate to be joined with the processing target substrate coated with the adhesive or the processing target substrate to be joined with the supporting substrate coated with the adhesive; a joint part joining the processing target substrate and the supporting substrate together via the adhesive by pressing the processing target substrate and the supporting substrate; and a transfer part transferring the processing target substrate, the supporting substrate or the superposed substrate to the delivery part, the reversing part, and the joint part. Further, the reversing part includes: another holding member holding the supporting substrate or the processing target substrate; a moving mechanism turning the supporting substrate or the processing target substrate held by the another holding member around a horizontal axis and moving the supporting substrate or the processing target substrate in a vertical direction and a horizontal direction; and a position adjusting mechanism adjusting an orientation in the horizontal direction of the supporting substrate or the processing target substrate held by the another holding member.

In this case, a cutout for holding an outer peripheral portion of the supporting

1-20. (canceled)

21. A joint system joining a processing target substrate and a supporting substrate together, comprising:
a joint processing station performing predetermined processing on the processing target substrate and the supporting substrate; and
a transfer-in/out station transferring the processing target substrate, the supporting substrate or a superposed substrate in which the processing target substrate and the supporting substrate are joined together into/from said joint processing station,
wherein said joint processing station comprises:
a coating unit applying an adhesive to the processing target substrate or the supporting substrate;
a first heat processing unit heating the processing target substrate or the supporting substrate coated with the adhesive to a first temperature;
a second heat processing unit further heating the processing target substrate or the supporting substrate which has been heated to the first temperature to a second temperature higher than the first temperature;
a joint unit joining the processing target substrate and the supporting substrate together via the adhesive by pressing the processing target substrate and the supporting substrate; and
a transfer region for transferring the processing target substrate, the supporting substrate or the superposed substrate to said coating unit, said first heat processing unit, said second heat processing unit, and said joint unit.

22. The joint system as set forth in claim 21, further comprising:
an inspection unit inspecting the superposed substrate joined in said joint unit.

23. The joint system as set forth in claim 21, further comprising:
a reversing unit reversing front and rear surfaces of the supporting substrate to be joined with the processing target substrate coated with the adhesive or the processing target substrate to be joined with the supporting substrate coated with the adhesive,
wherein, in said transfer region, the processing target substrate, the supporting substrate or the superposed substrate is further transferred to said reversing unit.

24. The joint system as set forth in claim 23,
wherein said reversing unit is provided integrally with said joint unit inside said joint unit, and
wherein said joint unit including said reversing unit comprises:
a delivery part for delivering the processing target substrate, the supporting substrate or the superposed substrate to/from an outside of said joint unit;
a reversing part reversing the front and rear surfaces of the supporting substrate to be joined with the processing target substrate coated with the adhesive or the processing target substrate to be joined with the supporting substrate coated with the adhesive;
a joint part joining the processing target substrate and the supporting substrate together via the adhesive by pressing the processing target substrate and the supporting substrate; and
a transfer part transferring the processing target substrate, the supporting substrate or the superposed substrate to said delivery part, said reversing part, and said joint part.

25. The joint system as set forth in claim 24,
wherein said transfer part comprises a first transfer arm including a first holding member holding the rear surface of the processing target substrate, the supporting substrate or the superposed substrate, and a second transfer arm including a second holding member holding an outer peripheral portion of the front surface of the processing target substrate or the supporting substrate, and
wherein said second holding member comprises a mounting part mounting the outer peripheral portion of the front surface of the processing target substrate or the supporting substrate, and a tapered part extending upward from said mounting part and having an inner side surface expanding in a tapered shape from a lower side to an upper side.

26. The joint system as set forth in claim 25,
wherein said first transfer arm comprises a guide member provided outside the processing target substrate, the supporting substrate or the superposed substrate held by said first holding member.

27. The joint system as set forth in claim 25,
wherein said first holding member holds the processing target substrate, the supporting substrate or the superposed substrate by a friction force.

28. The joint system as set forth in claim 24,
wherein said reversing part comprises a holding member holding the supporting substrate or the processing target substrate, a moving mechanism turning the supporting substrate or the processing target substrate held by said holding member around a horizontal axis and moving the supporting substrate or the processing target substrate in a vertical direction and a horizontal direction, and a position adjusting mechanism adjusting an orientation in the horizontal direction of the supporting substrate or the processing target substrate held by said holding member.

29. The joint system as set forth in claim 28,
wherein a cutout for holding an outer peripheral portion of the supporting substrate or the processing target substrate is formed in a side surface of said holding member.

30. The joint system as set forth in claim 24,
wherein a plurality of said delivery parts are arranged in a vertical direction.

31. A substrate processing system comprising a joint system joining a processing target substrate and a supporting substrate together,
wherein said joint system comprises:
a joint processing station performing predetermined processing on the processing target substrate and the supporting substrate; and
a transfer-in/out station transferring the processing target substrate, the supporting substrate or a superposed substrate in which the processing target substrate and the supporting substrate are joined together into/from said joint processing station,
wherein said joint processing station comprises:
a coating unit applying an adhesive to the processing target substrate or the supporting substrate;
a first heat processing unit heating the processing target substrate or the supporting substrate coated with the adhesive to a first temperature;
a second heat processing unit further heating the processing target substrate or the supporting substrate which has been heated to the first temperature to a second temperature higher than the first temperature;
a joint unit joining the processing target substrate and the supporting substrate together via the adhesive by pressing the processing target substrate and the supporting substrate; and
a transfer region for transferring the processing target substrate, the supporting substrate or the superposed substrate to said coating unit, said first heat processing unit, said second heat processing unit, and said joint unit,
wherein said substrate processing system further comprises a separation system separating the superposed substrate joined by said joint system into the processing target substrate and the supporting substrate,
wherein said separation system comprises:
a separation processing station performing predetermined processing on the processing target substrate, the supporting substrate, and the superposed substrate;
a transfer-in/out station transferring the processing target substrate, the supporting substrate or the superposed substrate into/from said separation processing station; and
a transfer unit transferring the processing target substrate, the supporting substrate or the superposed substrate between said separation processing station and said transfer-in/out station, and
wherein said separation processing station comprises:
a separation unit separating the superposed substrate into the processing target substrate and the supporting substrate;
a first cleaning unit cleaning the processing target substrate separated in said separation unit; and
a second cleaning unit cleaning the supporting substrate separated in said separation unit.

32. The substrate processing system as set forth in claim 31,
wherein said separation system further comprises an interface station transferring the processing target substrate between said separation processing station and a post-processing station performing predetermined post-processing on the processing target substrate separated in said separation processing station.

33. The substrate processing system as set forth in claim 32,
wherein the superposed substrate including a normal processing target substrate and the superposed substrate including a defective processing target substrate are transferred into said transfer-in/out station of said separation system, and
wherein said substrate processing system further comprises a control unit controlling said interface station and said transfer unit to transfer the normal processing target substrate to said post-processing station after the normal processing target substrate is cleaned in said second cleaning unit and to return the defective processing target substrate to said transfer-in/out station after the defective processing target substrate is cleaned in said first cleaning unit.

34. The substrate processing system as set forth in claim 32, further comprising:
an inspection unit provided between said separation processing station and said post-processing station for inspecting the processing target substrate.

35. A joint method of joining a processing target substrate and a supporting substrate together using a joint system,
wherein the joint system comprises:
a joint processing station comprising a coating unit applying an adhesive to the processing target substrate or the supporting substrate, a first heat processing unit heating the processing target substrate or the supporting substrate coated with the adhesive to a first temperature, a second heat processing unit further heating the processing target substrate or the supporting substrate which has been heated to the first temperature to a second temperature higher than the first temperature, a joint unit joining the processing target substrate and the supporting substrate together via the adhesive by pressing the processing target substrate and the supporting substrate, and a transfer region for transferring the processing target substrate, the supporting substrate or the superposed substrate to the coating unit, the first heat processing unit, the second heat processing unit, and the joint unit; and
a transfer-in/out station transferring the processing target substrate, the supporting substrate or the superposed substrate into/from the joint processing station, and
wherein said joint method comprises:
an adhesive coating step of applying the adhesive to the processing target substrate or the supporting substrate in the coating unit, then heating the processing target substrate or the supporting substrate to the first temperature in the first heat processing unit, and further heating the processing target substrate or the supporting substrate to the second temperature in the second heat processing unit; and
a joint step of then joining, in the joint unit, the processing target substrate or the supporting substrate coated with the adhesive in said adhesive coating step with the supporting substrate or the processing target.

36. The joint method as set forth in claim 35, further comprising:
an inspection step of inspecting the superposed substrate after said joint step.

37. The joint method as set forth in claim 35,
wherein the joint system further comprises a reversing unit reversing front and rear surfaces of the supporting substrate to be joined with the processing target substrate coated with the adhesive or the processing target substrate to be joined with the supporting substrate coated with the adhesive,
wherein said transfer region further transfers the processing target substrate, the supporting substrate or the superposed substrate to said reversing unit,
wherein said joint method further comprises a reversing step of reversing, in the reversing unit, the front and rear surfaces of the supporting substrate to be joined with the processing target substrate coated with the adhesive in said adhesive coating step or the processing target substrate to be joined with the supporting substrate coated with the adhesive in said adhesive coating step, and
wherein, in said joint step, the processing target substrate or the supporting substrate coated with the adhesive in said adhesive coating step is joined with the supporting substrate or the processing target substrate whose front and rear surfaces have been reversed in said reversing step.

38. The joint method as set forth in claim 37,
wherein the reversing unit is provided integrally with the joint unit inside the joint unit, and
wherein the joint unit including the reversing unit comprises: a delivery part for delivering the processing target substrate, the supporting substrate or the superposed substrate to/from an outside of the joint unit; a reversing part reversing the front and rear surfaces of the supporting substrate to be joined with the processing target substrate coated with the adhesive or the processing target substrate to be joined with the supporting substrate coated with the adhesive; a joint part joining the processing target substrate and the supporting substrate together via the adhesive by pressing the processing target substrate and the supporting substrate; and a transfer part transferring the processing target substrate, the supporting substrate or the superposed substrate to the delivery part, the reversing part, and the joint part,
wherein in said reversing step, the supporting substrate or the processing target substrate is transferred by the transfer part from the delivery part to the reversing part, and the front and rear surfaces of the supporting substrate or the processing target substrate are reversed in the reversing part, and
wherein in said joint step, the processing target substrate or the supporting substrate is transferred by the transfer part from the reversing part to the joint part, and the processing target substrate and the supporting substrate are joined together in the joint part.

39. The joint method as set forth in claim 38,
wherein the transfer part comprises a first transfer arm including a first holding member holding the rear surface of the processing target substrate, the supporting substrate or the superposed substrate, and a second transfer arm including a second holding member holding an outer peripheral portion of the front surface of the processing target substrate or the supporting substrate,
wherein the second holding member comprises a mounting part mounting the outer peripheral portion of the front surface of the processing target substrate or the supporting substrate, and a tapered part extending upward from the mounting part and having an inner side surface expanding in a tapered shape from a lower side to an upper side,
wherein in said joint step, the supporting substrate or the processing target substrate whose front and rear surfaces have been reversed in the reversing part is transferred by the second transfer arm to the joint part, and
wherein in said joint step, the processing target substrate or the supporting substrate whose front and rear surfaces have not been reversed in the reversing part is transferred by the first transfer arm to the joint part.

40. The joint method as set forth in claim 37,
wherein the reversing part comprises a holding member holding the supporting substrate or the processing target substrate, a moving mechanism turning the supporting substrate or the processing target substrate held by the holding member around a horizontal axis and moving the supporting substrate or the processing target substrate in a vertical direction and a horizontal direction, and a position adjusting mechanism adjusting an orientation in the horizontal direction of the supporting substrate or the processing target substrate held by the holding member, and
wherein in said reversing step, the supporting substrate or the processing target substrate held by the another holding member is adjusted in orientation in the horizontal direction by the position adjusting mechanism and then the front and rear surfaces thereof are reversed by the moving mechanism.
